(19) United States
(12) Patent Application Publication
(10) Pub. No.: US 2025/0081831 A1
(43) Pub. Date: Mar. 6, 2025

(54) DISPLAY SUBSTRATE AND DISPLAY DEVICE

(71) Applicants: CHENGDU BOE OPTOELECTRONICS TECHNOLOGY CO., LTD., Chengdu (CN); BOE TECHNOLOGY GROUP CO., LTD., Beijing (CN)

(72) Inventors: Tinghua SHANG, Beijing (CN); Yi ZHANG, Beijing (CN); Tingliang LIU, Beijing (CN); Huijuan YANG, Beijing (CN); Hongwei MA, Beijing (CN); Yang ZHOU, Beijing (CN); Qi QI, Beijing (CN); Chengjie QIN, Beijing (CN); Wei ZHANG, Beijing (CN); Ping WEN, Beijing (CN); Benlian WANG, Beijing (CN); Yue LONG, Beijing (CN); Weiyun HUANG, Beijing (CN)

(21) Appl. No.: 18/557,996

(22) PCT Filed: Oct. 11, 2022
(86) PCT No.: PCT/CN2022/124631

§ 371 Date: Oct. 30, 2023

(30) Foreign Application Priority Data
Nov. 30, 2021 (CN) 202111444104.8

(51) Int. Cl. H10K 59/88; H10K 59/80

(52) U.S. Cl. CPC H10K 59/88; H10K 59/8722; H10K 59/873

(57) ABSTRACT

Provided are a display substrate and a display device. In the display substrate, the first separation structure includes a first separation part and a second separation part which are stacked, the second separation structure includes a third separation part and a fourth separation part which are stacked, the second separation part has a first protruding part, the first protruding part protrudes relative to the first separation part, and at least one sub-functional layer of the light-emitting functional layer is disconnected at the first protruding part; the fourth separation part has a second protruding part, the second protruding part protrudes relative to the third separation part, and at least one sub-functional layer of the light-emitting functional layer is disconnected at the second protruding part; the first separation structure surrounds the light-emitting region; and the second separation structure is ring-shaped so as to surround the hole region.

### CROSS-REFERENCE TO RELATED APPLICATION

For all purposes, the present application claims the priority of the Chinese patent application No. 202111444104.8 filed on Nov. 30, 2021, the entire disclosure of which is incorporated herein by reference as part of the present application.

### TECHNICAL FIELD

Embodiments of the present disclosure relate to a display substrate and a display device.

### BACKGROUND

With the continuous development of display technology, organic light-emitting diode (OLED) display devices have become a research hotspot and technology development direction for major manufacturers owing to their advantages such as wide color gamut, high contrast, thin and light design, self-illumination, and wide viewing angle.

At present, organic light-emitting diode display devices have been widely used in various electronic products, ranging from small electronic products such as smart bracelets, smart watches, smart phones, and tablet computers to large electronic products such as laptops, desktops, and televisions. Therefore, the market demand for active matrix organic light-emitting diode display devices is also increasing.

### SUMMARY

Embodiments of the present disclosure provide a display substrate and a display device.

Embodiments of the present disclosure provide a display substrate, including: a base substrate, including a hole region, a display region, and a frame region located between the hole region and the display region; a plurality of sub-pixels located in the display region, the sub-pixel including a light-emitting element, the light-emitting element having a light-emitting region, the light-emitting element including a first electrode, a light-emitting functional layer, and a second electrode, the second electrode being located on a side of the light-emitting functional layer facing away from the base substrate, the first electrode being located on a side of the light-emitting functional layer close to the base substrate, and the light-emitting functional layer including a plurality of sub-functional layers; a first separation structure located in the display region and including a first separation part and a second separation part which are stacked, the first separation part being located on a side of the second separation part close to the base substrate; and a second separation structure located in the frame region and including a third separation part and a fourth separation part which are stacked, the third separation part being located on a side of the fourth separation part close to the base substrate; the second separation part has a first protruding part, the first protruding part protrudes relative to the first separation part, and at least one sub-functional layer of the light-emitting functional layer is disconnected at the first protruding part; the fourth separation part has a second protruding part, the second protruding part protrudes relative to the third separation part, and at least one sub-functional layer of the light-emitting functional layer is disconnected at the second protruding part; the first separation structure surrounds the light-emitting region; and the second separation structure is ring-shaped so as to surround the hole region.

According to the display substrate provided by the embodiments of the present disclosure, the second electrode is continuous at the first protruding part, and the first separation structure is arranged in a shape of a ring.

According to the display substrate provided by the embodiments of the present disclosure, the first separation structure is ring-shaped and arranged continuously.

According to the display substrate provided by the embodiments of the present disclosure, the first separation structure has a gap, the first electrode has a main body part and a connecting part, an orthographic projection of the main body part on the base substrate overlaps an orthographic projection of the light-emitting region on the base substrate, and the connecting part is located at the gap.

According to the display substrate provided by the embodiments of the present disclosure, the display substrate further includes an encapsulation layer, the encapsulation layer includes a first encapsulation layer, a second encapsulation layer, and a third encapsulation layer, the first encapsulation layer, the second encapsulation layer, and the third encapsulation layer are arranged in sequence, the first encapsulation layer is closer to the base substrate than the third encapsulation layer, the first encapsulation layer and the third encapsulation layer have a stacked contact portion, a plurality of second separation structures are provided, an orthographic projection of one of the plurality of second separation structures on the base substrate overlaps an orthographic projection of the second encapsulation layer on the base substrate, and an orthographic projection of another one of the plurality of second separation structures on the base substrate overlaps an orthographic projection of the stacked contact portion on the base substrate.

According to the display substrate provided by the embodiments of the present disclosure, the display substrate further includes a barrier dam, the barrier dam is located in the frame region, and the second separation structure includes two second separation structures located on both sides of the barrier dam, respectively.

According to the display substrate provided by the embodiments of the present disclosure, a thickness of the second separation part is greater than a thickness of the first separation part.

According to the display substrate provided by the embodiments of the present disclosure, a ratio of a thickness of the first separation part to a thickness of the second separation part is greater than or equal to 0.25 and less than or equal to 1.

According to the display substrate provided by the embodiments of the present disclosure, a dimension of the first separation part in a direction perpendicular to the base substrate is smaller than a dimension of the third separation part in a direction perpendicular to the base substrate.

According to the display substrate provided by the embodiments of the present disclosure, the second separation part and the fourth separation part are located in the same layer.

According to the display substrate provided by the embodiments of the present disclosure, the first separation structure and the second separation structure have the same layer structure.

According to the display substrate provided by the embodiments of the present disclosure, a count of film layers included in the first separation part is less than or equal to a count of film layers included in the third separation part.

According to the display substrate provided by the embodiments of the present disclosure, a material of the first separation structure includes a conductive material, and a material of the second separation structure includes a conductive material.

According to the display substrate provided by the embodiments of the present disclosure, the conductive material includes a metal and a conductive metal oxide.

According to the display substrate provided by the embodiments of the present disclosure, the second separation part and the fourth separation part are located in the same layer, and the third separation part includes a portion located in the same layer as the first separation part.

According to the display substrate provided by the embodiments of the present disclosure, a material of the first separation structure includes an inorganic insulating material, and a material of the second separation structure includes an inorganic insulating material.

According to the display substrate provided by the embodiments of the present disclosure, materials of the first separation part and the second separation part are different, materials of the third separation part and the fourth separation part are different, the materials of the first separation part and the third separation part are the same, and the materials of the second separation part and the fourth separation part are the same.

According to the display substrate provided by the embodiments of the present disclosure, materials of the first separation part and the third separation part include organic materials, and materials of the second separation part and the fourth separation part include inorganic insulating materials.

According to the display substrate provided by the embodiments of the present disclosure, materials of the first separation part and the third separation part include organic insulating materials, and materials of the second separation part and the fourth separation part include conductive materials.

According to the display substrate provided by the embodiments of the present disclosure, a material of the first separation part includes an organic insulating material, a material of the second separation part includes an organic insulating material, and a material of the third separation part includes an inorganic insulating material, and a material of the fourth separation part includes a conductive material.

According to the display substrate provided by the embodiments of the present disclosure, the first separation part and the second separation part are of an integral structure.

According to the display substrate provided by the embodiments of the present disclosure, the second separation structure includes two sub-separation structures, and second protruding parts of the two sub-separation structures are oppositely arranged.

According to the display substrate provided by the embodiments of the present disclosure, a plurality of second separation structures are provided, the second separation structure further includes a fifth separation part, a material of the fifth separation part includes a conductive material, fifth separation parts of the plurality of second separation structures are of an integral structure, and a plurality of fourth separation parts are sequentially arranged around the hole region.

According to the display substrate provided by the embodiments of the present disclosure, the display substrate further includes a conductive structure, an orthographic projection of the conductive structure on the base substrate overlaps an orthographic projection of the first separation structure on the base substrate.

According to the display substrate provided by the embodiments of the present disclosure, the conductive structure includes a data line or a power line.

According to the display substrate provided by the embodiments of the present disclosure, the first separation structure is T-shaped.

According to the display substrate provided by the embodiments of the present disclosure, the separation structure includes at least one separation sub-structure, and an orthographic projection of the at least one separation sub-structure on the base substrate at least surrounds one half of an orthographic projection of the light-emitting region on the base substrate.

Embodiments of the present disclosure further provides a display device, including any one of the display substrates as described above.

### BRIEF DESCRIPTION OF THE DRAWINGS

In order to more clearly illustrate the technical solution of the embodiments of the present disclosure, the drawings of the embodiments will be briefly described in the following. It is obvious that the described drawings below are only related to some embodiments of the present disclosure without constituting any limitation thereto.

FIG. 1 is a schematic diagram of a light-emitting element.

FIG. 2 is a schematic diagram of a display substrate.

FIG. 3 is a schematic diagram of a display substrate.

FIG. 4 is a schematic cross-sectional view of a display substrate provided by an embodiment of the present disclosure.

FIG. 5A is an enlarged view of the first separation structure in FIG. 4.

FIG. 5B is an enlarged view of the second separation structure in FIG. 4.

FIG. 6A to FIG. 6D are flow charts of a manufacturing method of the display substrate illustrated in FIG. 4.

FIG. 7 is a schematic cross-sectional view of a display substrate provided by an embodiment of the present disclosure.

FIG. 8A is an enlarged view of the first separation structure in FIG. 7.

FIG. 8B is an enlarged view of the second separation structure in FIG. 7.

FIG. 9A to FIG. 9C are flow charts of a manufacturing method of the display substrate illustrated in FIG. 7.

FIG. 10 is a schematic cross-sectional view of a display substrate provided by an embodiment of the present disclosure.

FIG. 11A is a schematic cross-sectional view of another display substrate provided by an embodiment of the present disclosure.

FIG. 11B is a schematic cross-sectional view of another display substrate provided by an embodiment of the present disclosure.

FIG. 11C is a schematic cross-sectional view of another display substrate provided by an embodiment of the present disclosure.

FIG. 12A is a flow chart of manufacturing a display substrate provided by an embodiment of the present disclosure.

FIG. 12B is a flow chart of manufacturing a display substrate provided by an embodiment of the present disclosure.

FIG. 13 is a schematic plan view of a plurality of second separation structures in a display substrate provided by an embodiment of the present disclosure.

FIG. 14 is a schematic plan view of a first separation structure and a first electrode in the display substrate illustrated in FIG. 10.

FIG. 15 is a schematic plan view of a first separation structure and a conductive structure in the display substrate illustrated in FIG. 11A or FIG. 11B.

FIG. 16 is a schematic plan view of a first separation structure in the display substrate illustrated in FIG. 10.

FIG. 17 is a schematic cross-sectional view of a display substrate provided by an embodiment of the present disclosure.

FIG. 18A is a schematic cross-sectional view of another display substrate provided by an embodiment of the present disclosure.

FIG. 18B is a schematic cross-sectional view of another display substrate provided by an embodiment of the present disclosure.

FIG. 18C is a schematic cross-sectional view of another display substrate provided by an embodiment of the present disclosure.

FIG. 19A is a flow chart of manufacturing a display substrate provided by an embodiment of the present disclosure.

FIG. 19B is a flow chart of manufacturing a display substrate provided by an embodiment of the present disclosure.

FIG. 20 is a schematic cross-sectional view of a display substrate provided by an embodiment of the present disclosure.

FIG. 21 is a flow chart of manufacturing the display substrate illustrated in FIG. 20.

FIG. 22 is a plan view of a second separation structure in a frame region of the display substrate illustrated in FIG. 20.

FIG. 23 is a plan view of a first separation structure in a display region of a display substrate provided by an embodiment of the present disclosure.

FIG. 24 is a plan view of a first separation structure in a display region of a display substrate provided by an embodiment of the present disclosure.

FIG. 25A is a schematic plan view of another display substrate provided by an embodiment of the present disclosure.

FIG. 25B is a schematic plan view of another display substrate provided by an embodiment of the present disclosure.

FIG. 26 is a schematic diagram of light-emitting elements in a display substrate provided by an embodiment of the present disclosure.

FIG. 27 is a schematic diagram of a pixel circuit and a light-emitting element in a display substrate.

FIG. 28 is a schematic diagram of a display device provided by an embodiment of the present disclosure.

### DETAILED DESCRIPTION

In order to make objectives, technical details and advantages of the embodiments of the present disclosure more clear, the technical solutions of the embodiments will be described in a clearly and fully understandable way in connection with the drawings related to the embodiments of the present disclosure. Apparently, the described embodiments are just a part but not all of the embodiments of the present disclosure. Based on the described embodiments herein, those skilled in the art can obtain other embodiment(s), without any inventive work, which should be within the scope of the present disclosure.

Unless otherwise defined, all the technical and scientific terms used herein have the same meanings as commonly understood by one of ordinary skill in the art to which the present disclosure belongs. The terms “first,” “second,” etc., which are used in the present disclosure, are not intended to indicate any sequence, amount or importance, but distinguish various components. Also, the terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “On,” “under,” “right,” “left” and the like are only used to indicate relative position relationship, and when the position of the described object is changed, the relative position relationship may be changed accordingly.

With the continuous development of display technology, people's pursuit of display quality is getting higher and higher. In order to further reduce power consumption and achieve high brightness, one light-emitting layer in the light-emitting element in an OLED display panel can be replaced by two light-emitting layers, a charge generation layer (CGL) is added between the two light-emitting layers, and N/P-CGL is used as a heterojunction to connect two light-emitting devices in series to form a double-stack design, thereby forming a tandem structure. The display substrate with the tandem structure realizes the series connection of double light-emitting devices, thus greatly reducing the luminous current of the light-emitting element under the same luminous intensity, increasing the lifespan of the light-emitting element, and facilitating the development and mass production of new technologies such as vehicles with a long lifespan. A display device with a tandem structure has the advantages such as a long lifespan, low power consumption, high brightness, and the like.

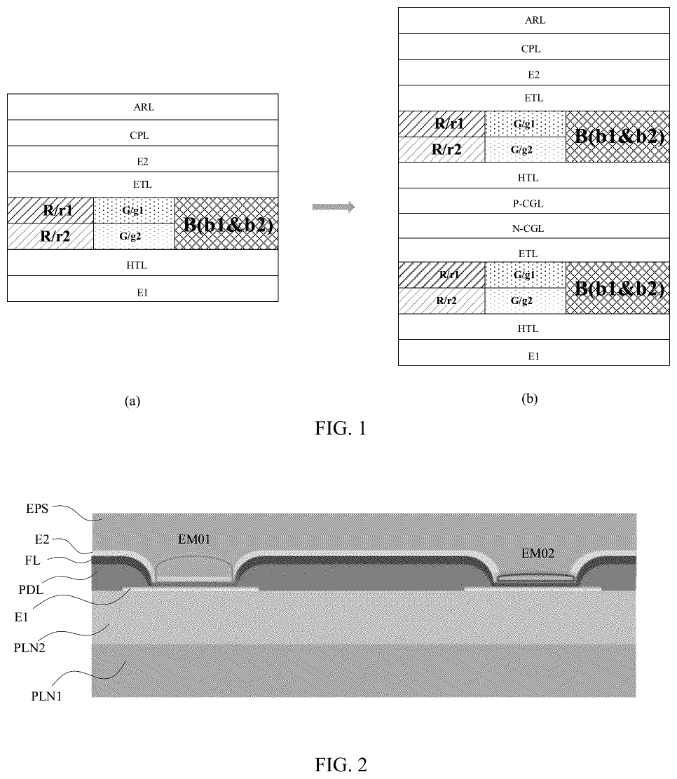

FIG. 1 is a schematic diagram of a light-emitting element. FIG. 1(a) is a schematic diagram of a traditional light-emitting element. FIG. 1(b) is a schematic diagram of a light-emitting element with a tandem structure. As illustrated in FIG. 1(b), the charge generation layer (CGL) between different light-emitting elements having tandem structures are connected.

FIG. 1 illustrates a first electrode E1, a second electrode E2, a hole transport layer HTL, an electron transport layer ETL, a light coupling layer CPL, an anti-reflection layer ARL, a P-type doped charge generation layer P-CGL, an N-type doped charge generation layer N-CGL, a light-emitting layer R, a light-emitting layer G, and a light-emitting layer B. The light-emitting layer R includes two sublayers including a light-emitting material r1 and a light-emitting material r2 respectively, the light-emitting layer G includes two sublayers including a light-emitting material g1 and a light-emitting material g2 respectively, and the light-emitting layer B includes a light-emitting material b1 and a light-emitting material b2. The light-emitting material r1 and the light-emitting material r2 are two different materials that emit red light, the light-emitting material g1 and the light-emitting material g2 are two different materials that emit green light, and the light-emitting material b1 and the light-emitting material b2 are two different materials that emit blue light.

FIG. 2 is a schematic diagram of a display substrate. As illustrated in FIG. 2, the display substrate includes a planarization layer PLN1, a planarization layer PLN2, a pixel-defining layer PDL, an electrode E1, a light-emitting functional layer FL, an electrode E2, and an encapsulation layer EPS. FIG. 1 illustrates the light-emitting element EM01 and the light-emitting element EM02, the charge generation layers (CGLs) of the light-emitting element EM01 and the light-emitting element EM02 can be of an integral structure and can be fabricated by using an open mask.

However, the inventor(s) noticed that for high-resolution products, because the charge generation layer has high conductivity and the light-emitting functional layers (the light-emitting functional layer herein refers to a film layer including two light-emitting layers and a charge generation layer) of adjacent sub-pixels are connected, the charge generation layer (sub-functional layer) is likely to cause crosstalk between adjacent sub-pixels, thereby affecting the product quality and seriously affecting the display quality.

For example, crosstalk between adjacent sub-pixels refers to a situation where a light-emitting element that should not emit light emits light. As illustrated in FIG. 2, if the desired situation is that the light-emitting element EM01 emits light and the light-emitting element EM02 does not emit light, but due to the conductivity of the charge generation layer, the light-emitting element EM02 also emits light, thus leading to crosstalk.

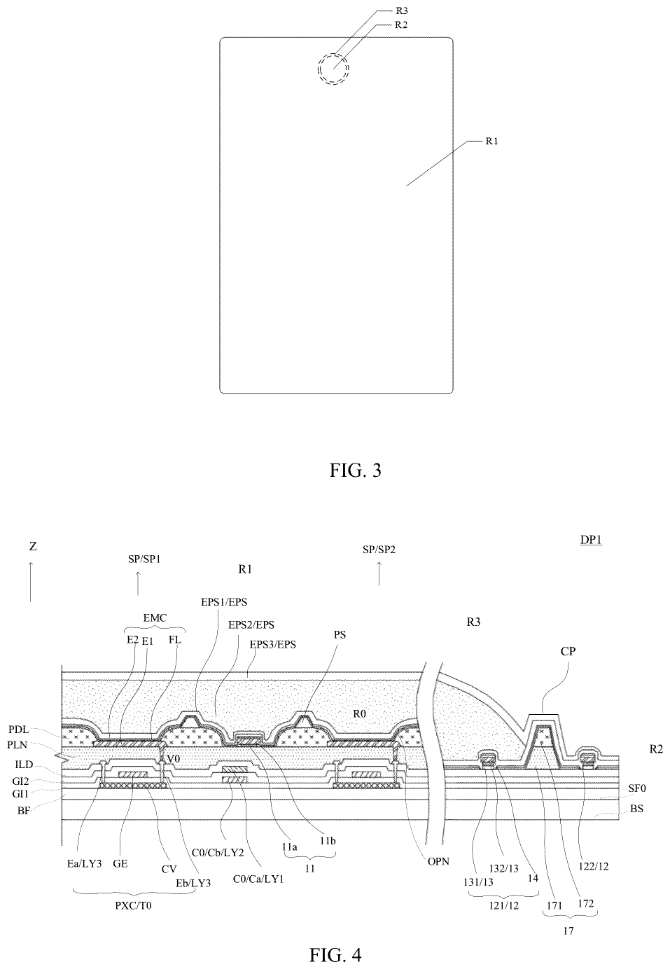

FIG. 3 is a schematic diagram of a display substrate. As illustrated in FIG. 3, the display substrate includes a hole region R2, a display region R1, and a frame region R3 located between the hole region R2 and the display region R1. As illustrated in FIG. 3, the hole region R2 is circular. It should be noted that the embodiments of the present disclosure are illustrated by taking as an example that the shape of the hole region R2 is a circle, but the shape of the hole region R2 may also be of any other suitable shape and is not limited to a circle. Moreover, the position of the hole region R2 is not limited to what is illustrated in the figure, and can be set as required. For example, some of the gate lines, some of the data lines, and other wires surround the hole region R2 to form the frame region R3.

For example, when the scheme of perforating in the screen is adopted, at least some structures in the hole region R2 are removed, that is, part of the display region needs to be sacrificed in the scheme of perforating in the screen so as to form the hole region. For example, all structures in the hole region R2 of the display substrate are removed. For example, after the encapsulation layer is formed, the portion of the display substrate located in the hole region R2 is removed by hole digging. Part of the sensor can be disposed in the hole region R2, or all of the sensor can be disposed in the hole region R2. For example, the sensor includes a camera.

On the one hand, in order to prevent water and oxygen from invading the light-emitting element, a separation structure can be provided in the frame region R3 so as to separate the light-emitting functional layer of the light-emitting element, thereby preventing water and oxygen from entering the display region R1 along the light-emitting functional layer around the hole region R2.

On the other hand, in order to reduce or avoid the crosstalk problem caused by the sub-functional layer with high conductivity in the light-emitting functional layer, a separation structure can be provided in the display region.

In the display substrate provided by the embodiments of the present disclosure, a first separation structure is provided in the display region R2 so as to improve the reliability of the display substrate, and a second separation structure is provided in the frame region R3 so as to to reduce or avoid crosstalk.

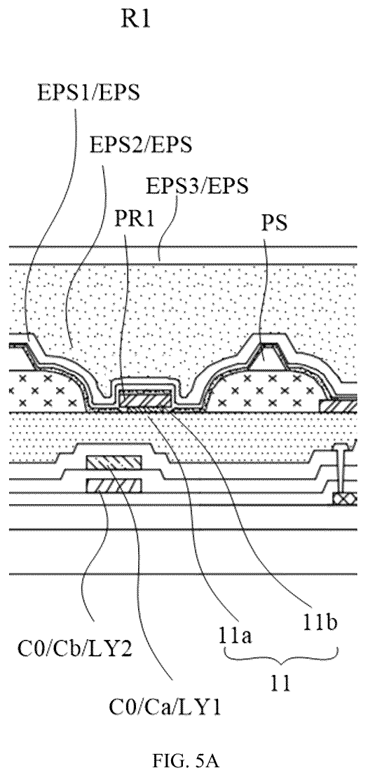

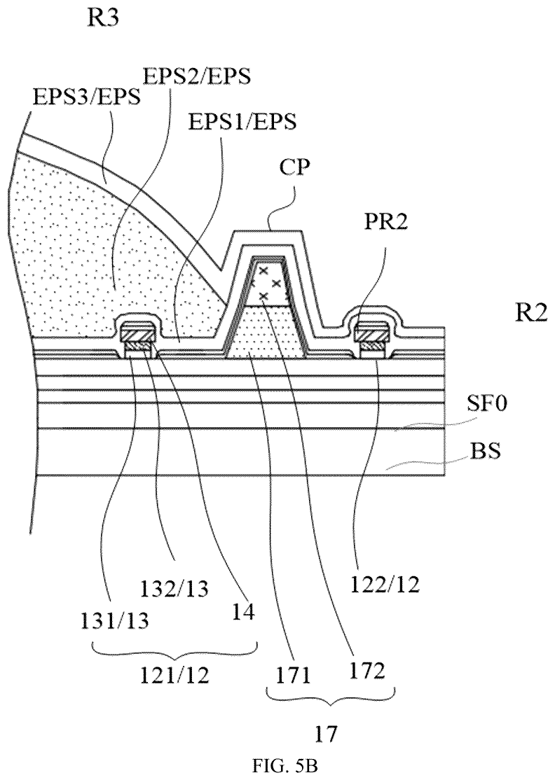

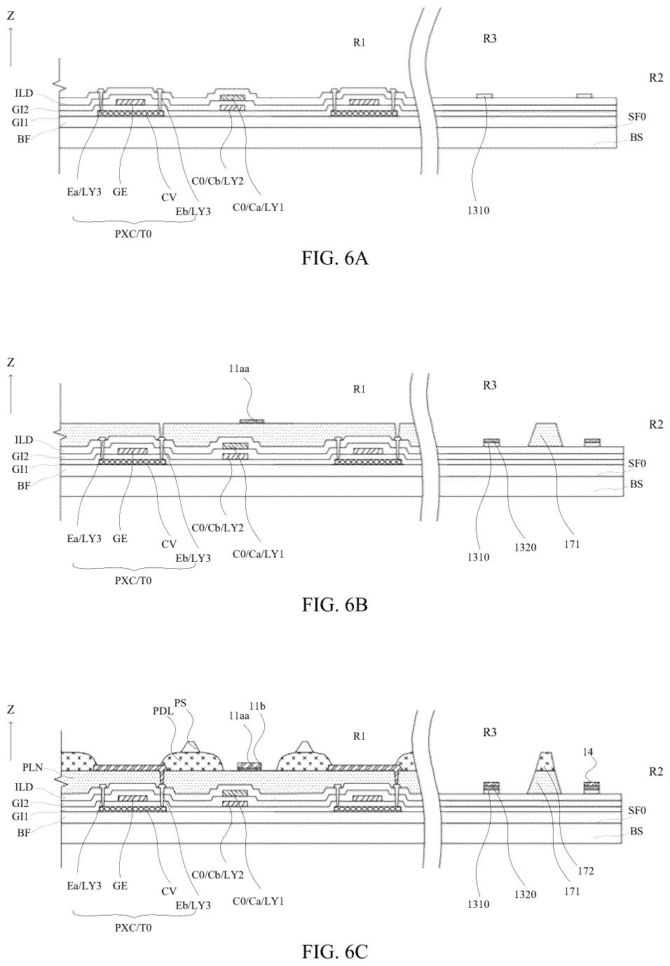

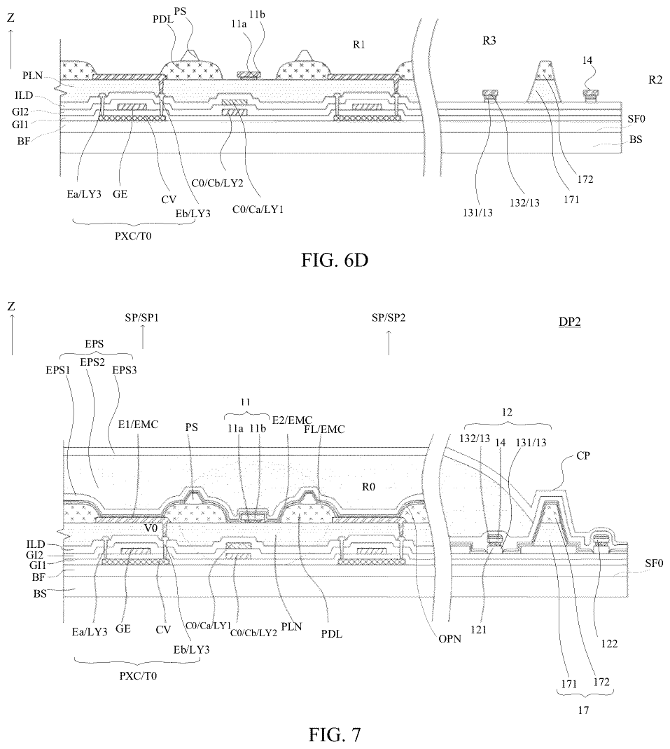

FIG. 4 is a schematic cross-sectional view of a display substrate provided by an embodiment of the present disclosure. FIG. 5A is an enlarged view of the first separation structure in FIG. 4. FIG. 5B is an enlarged view of the second separation structure in FIG. 4. FIG. 6A to FIG. 6D are flow charts of a manufacturing method of the display substrate illustrated in FIG. 4.

As illustrated in FIG. 4, the display substrate DP1 includes: a base substrate BS, a plurality of sub-pixels SP, a first separation structure 11, and a second separation structure 12. As illustrated in FIG. 4, the base substrate BS includes a hole region R2, a display region R1, and a frame region R3 located between the hole region R2 and the display region R1.

As illustrated in FIG. 4, the plurality of sub-pixels SP are located on the main surface SFO of the base substrate BS, the sub-pixel SP includes a light-emitting element EMC, and the light-emitting element EMC has a light-emitting region R0.

As illustrated in FIG. 4, the light-emitting element EMC includes a first electrode E1, a light-emitting functional layer FL, and a second electrode E2. The second electrode E2 is located on the side of the light-emitting functional layer FL facing away from the base substrate BS. The first electrode E1 is located on the side of the light-emitting functional layer FL close to the base substrate BS. The light-emitting functional layer FL includes a plurality of sub-functional layers.

For example, the first electrode E1 is made of a conductive material. For example, the material of the first electrode E1 includes a metal and a conductive metal oxide. For example, a stacked structure of indium tin oxide (ITO), silver (Ag), and indium tin oxide (ITO) is adopted for the first electrode E1. The material and structure of the first electrode E1 can be set as required.

For example, the second electrode E2 is made of a conductive material. For example, the material of the second electrode E2 includes a metal or alloy. For example, the material of the second electrode E2 includes Mg/Ag alloy. The material and structure of the second electrode E2 can be set as required.

For example, the second electrodes E2 of different sub-pixels are electrically connected so as to provide the same voltage signal.

As illustrated in FIG. 4 and FIG. 5A, the first separation structure 11 is located in the display region R1, the first separation structure 11 is located between the light-emitting regions R0 of adjacent sub-pixels SP and includes a first separation part 11a and a second separation part 11b which are stacked, and the first separation part 11a is located on the side of the second separation part 11b close to the base substrate BS; the second separation part 11b has a protruding part PR1, and the protruding part PR1 protrudes relative to the first separation part 11a. For example, the protruding part PR1 protrudes relative to at least a portion of the first separation part 11a. For example, the protruding part PR1 protrudes relative to the side of the first separation part 11a close to the second separation part 11b, and at least one sub-functional layer of the light-emitting functional layer FL is disconnected at the protruding part PR1. For example, the direction from the first electrode E1 to the second electrode E2 is the direction Z. The first separation structure 11 has a protruding part PR1, thus facilitating separation of at least one sub-functional layer of the light-emitting functional layer FL.

For example, disconnection of one element at the protruding PR1 includes disconnection at the side surface of the protruding part PR1.

As illustrated in FIG. 4 and FIG. 5B, the second separation structure 12 is located in the frame region R3 and includes a third separation part 13 and a fourth separation part 14 which are stacked. The third separation part 13 is located on the side of the fourth separation part 14 close to the base substrate BS.

As illustrated in FIG. 4, the fourth separation part 14 has a protruding part PR2 protruding relative to the third separation part 13, and at least one sub-functional layer of the light-emitting functional layer FL is disconnected at the protruding part PR2. For example, the protruding part PR2 protrudes relative to the side of the third separation part 13 close to the fourth separation part 14.

As illustrated in FIG. 4, the display substrate includes a buffer layer BF, an insulating layer GI1, an insulating layer GI2, an insulating layer ILD, a planarization layer PLN, a pixel-defining pattern PDL, and a spacer PS. The spacer PS is configured to support a fine metal mask when forming a light-emitting layer. For example, as illustrated in FIG. 4, the pixel-defining pattern PDL includes a plurality of openings OPN configured to define the light-emitting region R0 of the sub-pixel SP and configured to expose at least a portion of the first electrode E1.

FIG. 4 also illustrates a thin film transistor T0. The thin film transistor T0 includes a gate electrode GE, an active layer CV, a source electrode Ea, and a drain electrode Eb. The first electrode E1 is connected to the drain electrode Eb. The source electrode Ea and the drain electrode Eb of the thin film transistor may be identical in structure and interchangeable in terms of names.

FIG. 4 also illustrates the first electrode plate Ca and the second electrode plate Cb of the capacitor C0. For example, the capacitor C0 may be the storage capacitor Cst mentioned later, but is not limited thereto.

FIG. 4 also illustrates the encapsulation layer EPS. For example, the encapsulation layer EPS includes a first encapsulation layer EPS1, a second encapsulation layer EPS2, and a third encapsulation layer EPS3. For example, the first encapsulation layer EPS1 and the third encapsulation layer EPS3 are inorganic layers and can be formed by chemical vapor deposition (CVD) processes, respectively. The second encapsulation layer EPS2 is an organic layer and can be formed by an inkjet printing process. As illustrated in FIG. 4, the thickness of the second encapsulation layer EPS2 is greater than the thickness of the first encapsulation layer EPS1. As illustrated in FIG. 4, the thickness of the second encapsulation layer EPS2 is greater than the thickness of the third encapsulation layer EPS3.

As illustrated in FIG. 4, in the frame region R3, the first encapsulation layer EPS1 and the third encapsulation layer EPS3 are in contact to form a stacked contact portion CP.

For example, in the case where the thickness of the second separation part 11b is greater than the thickness of the first separation part 11a, encapsulation of the encapsulation layer EPS is better facilitated.

For example, in the case where the difference in thickness between the two separation parts of the separation structure is small, encapsulation of the encapsulation layer EPS is better facilitated, thereby improving the encapsulation effect.

For example, in the case where the ratio of the thickness of the first separation part 11a to the thickness of the second separation part 11b is greater than or equal to 0.25 and less than or equal to 1, encapsulation of the encapsulation layer EPS is better facilitated.

FIG. 4 and FIG. 5B also illustrate the barrier dam 17. The barrier dam 17 includes a sub-dam 171 and a sub-dam 172. For example, the sub-dam 171 and the planarization layer PLN are located in the same layer, and are formed from the same film layer using the same patterning process. For example, the sub-dam 172 and the pixel-defining pattern PDL are located in the same layer, and are formed from the same film layer using the same patterning process.

As illustrated in FIG. 4 and FIG. 5B, the display substrate includes two second separation structures 12: a separation structure 121 and a separation structure 122, the separation structure 121 and the separation structure 122 are arranged on both sides of the barrier dam 17 respectively. The dimension of the barrier dam 17 in the direction (direction Z) perpendicular to the base substrate BS is greater than the dimension of the second separation structure 12 in the direction perpendicular to the base substrate BS. FIG. 4 and FIG. 5B only illustrate two second separation structures 12, and it should be noted that three or more second separation structures 12 may also be provided.

As illustrated in FIG. 4 and FIG. 5B, the orthographic projection of the separation structure 121 on the base substrate BS overlaps the orthographic projection of the second encapsulation layer EPS2 on the base substrate BS, and the orthographic projection of the separation structure 122 on the base substrate BS overlaps the orthographic projection of the stacked contact portion CP on the base substrate BS.

FIG. 4 and FIG. 5B are illustrated by taking as an example that the orthographic projection of one second separation structure 12 on the base substrate BS overlaps the orthographic projection of the second encapsulation layer EPS2 on the base substrate BS, but are not limited thereto. For example, in some other embodiments, the orthographic projection of a plurality of second separation structures 12 on the base substrate BS overlaps the orthographic projection of the second encapsulation layer EPS2 on the base substrate BS.

FIG. 4 and FIG. 5B are illustrated by taking as an example that the orthographic projection of one second separation structure 12 on the base substrate BS overlaps the orthographic projection of the stacked contact portion CP on the base substrate BS, but are not limited thereto. For example, in some other embodiments, the orthographic projection of a plurality of second separation structures 12 on the base substrate BS overlaps the orthographic projection of the stacked contact portion CP on the base substrate BS.

For example, as illustrated in FIG. 4 and FIG. 5B, at least one second separation structure 12 is provided on the left side of the barrier dam 17, and in some embodiments of the present disclosure, three to seven second separation structures 12 are provided on the left side of the barrier dam 17. For example, as illustrated in FIG. 4 and FIG. 5B, at least one second separation structure 12 is provided on the right side of the barrier dam 17, and in some embodiments of the present disclosure, three to seven second separation structures 12 are provided on the right side of the barrier dam 17.

As illustrated in FIG. 4 and FIG. 5B, the orthographic projection of the separation structure 122 on the base substrate BS does not overlap the orthographic projection of the second encapsulation layer EPS2 on the base substrate BS.

As illustrated in FIG. 4, the first conductive pattern layer LY1 includes a gate electrode GE and a first electrode plate Ca, the second conductive pattern layer LY2 includes a second electrode plate Cb, and the third conductive pattern layer LY3 includes a source electrode Ea and a drain electrode Eb. For example, the third conductive pattern layer LY3 may include a plurality of sublayers which are stacked, for example, the third conductive pattern layer LY3 may include a stacked structure of three sublayers Ti/Al/Ti.

For example, as illustrated in FIG. 4, the first separation part 11a may be a metal layer, for example, a Mo layer. For example, as illustrated in FIG. 4, the thickness of the first separation part 11a is 500-5000 Å. Because the material of the first separation part 11a is a metal material, for example, the metal Mo, the thickness is small. As such, the first separation structure 11 is enabled to separate the light-emitting functional layer FL, but not to separate the second electrode E2, thus helping keep the second electrode E2 continuous and improving the uniformity of luminescence of the display substrate.

For example, as illustrated in FIG. 4, the thickness of the first separation part 11a is smaller than the thickness of the second separation part 11b.

For example, as illustrated in FIG. 4, the third separation part 13 includes a sublayer 131 and a sublayer 132. For example, the sublayer 131 may be located in the same layer as the source electrode Ea and the drain electrode Eb of the thin film transistor. For example, the sublayer 132 may be located in the same layer as the first separation part 11a.

For example, as illustrated in FIG. 4, the material of the first separation part 11a includes Mo, and the material of the third separation part 13 includes Mo, Al, and Ti. The third separation part 13 includes a portion located in the same layer as the first separation part 11a. That is, the third separation part 13 includes a sublayer 132 located in the same layer as the first separation part 11a.

For example, as illustrated in FIG. 4, the second separation part 11b and the fourth separation part 14 are located in the same layer. Both the second separation part 11b and the fourth separation part 14 may be located in the same layer as the first electrode E1.

As illustrated in FIG. 4, the thickness of the third separation part 13 of the second separation structure 12 is greater than the thickness of the first separation part 11a of the first separation structure 11, so that both the light-emitting functional layer FL and the second electrode E2 are separated in the frame region R3 near the hole region R2, thereby separating the light-emitting material between the display region and the hole, preventing water and oxygen around the hole from entering the display region R1 along the light-emitting material, and improving the service life of the light-emitting element.

As illustrated in FIG. 4, according to the display substrate provided by the embodiments of the present disclosure, the display substrate further includes a pixel circuit PXC configured to drive the light-emitting element EMC to emit light, and the first electrode E1 is connected to the pixel circuit PXC by means of the via hole VO running through the planarization layer PLN.

For example, as illustrated in FIG. 4, the plurality of sub-pixels SP include a sub-pixel SP1 and a sub-pixel SP2. The sub-pixel SP1 and the sub-pixel SP2 are two adjacent sub-pixels. The number of sub-pixels provided on the display substrate is not limited to what is illustrated in the figure, and can be set as required.

In the embodiments of the present disclosure, the number of sub-functional layers included in the light-emitting functional layer FL can be set as required.

In the display substrate provided by the embodiments of the present disclosure, the first separation structure can be provided between adjacent sub-pixels, and at least one of the plurality of sub-functional layers in the light-emitting functional layer is disconnected at the position where the separation structure is located. Thus, the resistance of the sub-functional layer with high conductivity in the light-emitting functional layer FL is increased, thereby reducing or avoiding the crosstalk between adjacent sub-pixels caused by the film layer with high conductivity in the plurality of sub-functional layers, and reducing or preventing the occurrence of crosstalk when a light-emitting element emits light.

In the display substrate provided by the embodiments of the present disclosure, the first separation structure 11 is formed after the first electrode E1 is formed, without changing the backplane structure of the display substrate. In addition, the first separation structure 11 is disposed between the first electrodes E1 of the light-emitting element, so that there is a large space to arrange the separation structure 11, thus facilitating the arrangement of separation structures 10 of different structures.

The material of the first separation structure 11 and the material of the second separation structure 12 illustrated in FIG. 4 are both conductive materials. The first separation structure 11 can separate the organic light-emitting material, and can be arranged between adjacent sub-pixels in the display region.

FIG. 6A to FIG. 6D illustrate a manufacturing method of the display substrate DP1. The manufacturing method of the display substrate DP1 includes the following steps.

As illustrated in FIG. 6A, the manufacturing method of the display substrate includes: forming a buffer layer BF on the base substrate, then forming an active layer CV on the buffer layer BF, and forming an insulating layer GI1 on the active layer CV. the manufacturing method further includes: forming a gate electrode GE and a first electrode plate Ca on the insulating layer GI1, forming an insulating layer GI2 on the gate electrode GE and the first electrode plate Ca, forming a second electrode plate Cb on the insulating layer GI2, forming an insulating layer ILD on the second electrode plate Cb, and forming a source electrode Ea, a drain electrode Eb, and an intermediate sublayer 1310 on the insulating layer ILD.

As illustrated in FIG. 6B, forming a planarization layer PLN on the source electrode Ea and the drain electrode Eb and forming a sub-dam 171 in the frame region, forming an intermediate layer 11aa in the display region and forming an intermediate sublayer 1320 in the frame region.

As illustrated in FIG. 6C, forming a first electrode E1 and a second separation part 11b in the display region, and forming a fourth separation part 14 in the frame region; forming a pixel-defining pattern PDL and a spacer PS in the display region, and forming a sub-dam 172 in the frame region.

As illustrated in FIG. 6D, etching the intermediate layer 11aa, the intermediate sublayer 1310, and the intermediate sublayer 1320 to form a first separation part 11a and a third separation part 13.

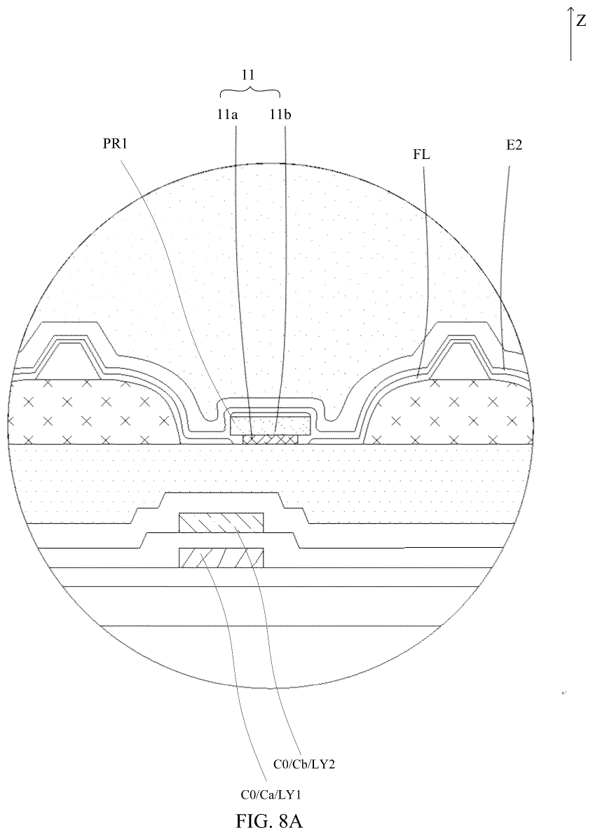

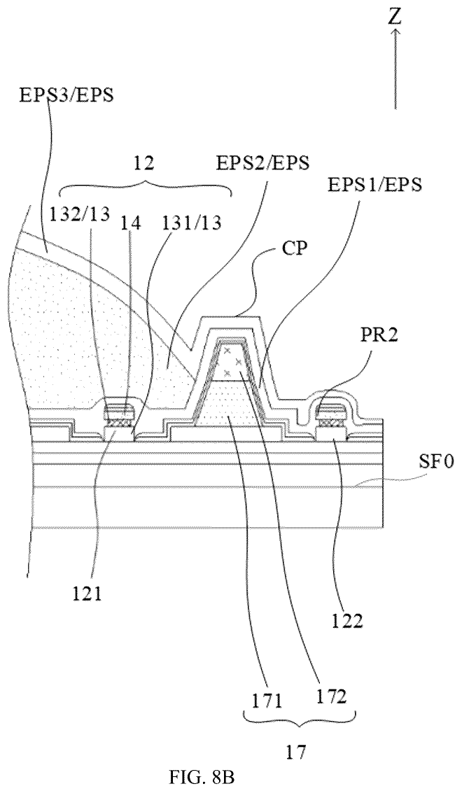

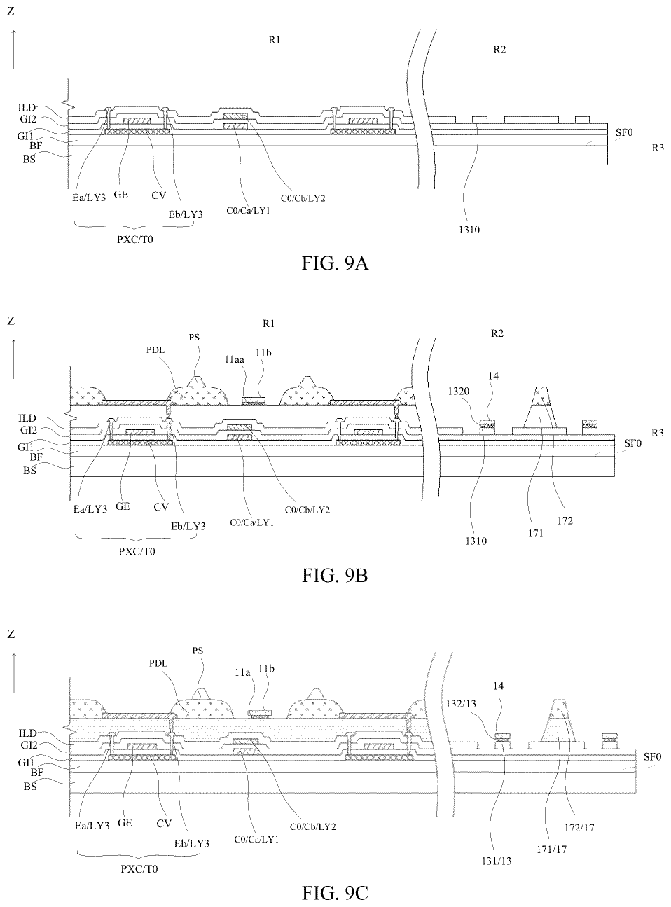

FIG. 7 is a schematic cross-sectional view of a display substrate provided by an embodiment of the present disclosure. FIG. 8A is an enlarged view of the first separation structure in FIG. 7. FIG. 8B is an enlarged view of the second separation structure in FIG. 7. FIG. 9A to FIG. 9C are flow charts of a manufacturing method of the display substrate illustrated in FIG. 7.

The display substrate DP2 illustrated in FIG. 7 differs from the display substrate DP1 illustrated in FIG. 4 in that: the first separation structure 11 and the second separation structure 12 illustrated in FIG. 7 are both inorganic insulating structures.

As illustrated in FIG. 7, the first separation structure 11 includes a first separation part 11a and a second separation part 11b. Both the first separation part 11a and the second separation part 11b are made of inorganic insulating materials.

As illustrated in FIG. 7, the second separation structure 12 includes a third separation part 13 and a fourth separation part 14. The third separation part 13 includes a sublayer 131 and a sublayer 132. Both the third separation part 13 (the sublayer 131 and the sublayer 132) and the fourth separation part 14 are made of inorganic insulating materials.

For example, as illustrated in FIG. 7, the inorganic insulating material used in the first separation part 11a, the second separation part 11b, the third separation part 13, and the fourth separation part 14 includes at least one of SiOx, SiNy and SiOxNy.

As illustrated in FIG. 7, FIG. 8A and FIG. 8B, the first separation structure 11 is T-shaped, and the second separation structure 12 includes a T-shaped portion.

Of course, the first separation structure 11 is not limited to a T-shape, and in other embodiments, the first separation structure 11 may also be in an I-shape, or another suitable shape may also be adopted. The second separation structure 12 can be T-shaped or I-shaped, and of course, other suitable shapes can also be adopted.

FIG. 9A to FIG. 9C illustrate a manufacturing method of the display substrate DP2. The manufacturing method of the display substrate includes the following steps.

As illustrated in FIG. 9A, the manufacturing method includes: forming a buffer layer BF on the base substrate, then forming an active layer CV on the buffer layer BF, and forming an insulating layer GI1 on the active layer CV. The manufacturing method includes: forming a gate electrode GE and a first electrode plate Ca on the insulating layer GI1, forming an insulating layer GI2 on the gate electrode GE and the first electrode plate Ca, forming a second electrode plate Cb on the insulating layer GI2, forming an insulating layer ILD and an intermediate sublayer 1310 on the second electrode plate Cb, and forming a source electrode Ea and a drain electrode Eb on the insulating layer ILD.

As illustrated in FIG. 9B, forming a planarization layer PLN on the source electrode Ea and the drain electrode Eb, and forming a sub-dam 171 in the frame region; forming an intermediate layer 11aa in the display region and forming an intermediate sublayer 1320 in the frame region; forming a second separation part 11b in the display region, and forming a fourth separation part 14 in the frame region; forming a first electrode E1 in the display region; forming a pixel-defining pattern PDL in the display region and forming a sub-dam 172 in the frame region; and forming a spacer PS.

As illustrated in FIG. 9C, etching the intermediate layer 11aa, the intermediate sublayer 1310, and the intermediate sublayer 1320 to form a first separation part 11a and a third separation part 13.

For example, as illustrated in FIG. 7, different inorganic insulating materials are used for the first separation part 11a and the second separation part 11b, so as to facilitate the formation of a first separation structure 11 having a protruding part. For example, as illustrated in FIG. 7, different inorganic insulating materials are used for the third separation part 13 and the fourth separation part 14, so as to facilitate the formation of a second separation structure 12 having a protruding part.

For example, as illustrated in FIG. 7, the first separation part 11a and the sublayer 132 of the third separation part 13 are located in the same layer, and the second separation part 11b and the fourth separation part 14 are located in the same layer.

For example, as illustrated in FIG. 7, the thickness of the first separation part 11a made of an inorganic insulating material is 500-5000 Å, and the thickness of the sublayer 132 of the third separation part 13 made of an inorganic insulating material is 500-5000 Å.

As illustrated in FIG. 7 and FIG. 9A, the sublayer 131 and the insulating layer ILD are located in the same layer.

As illustrated in FIG. 7 and FIG. 9C, the sublayer 132 is retracted relative to the sublayer 131 and the fourth separation part 14, so as to facilitate separation of the light-emitting functional layer FL and the second electrode E2.

As illustrated in FIG. 7, the barrier dam 17 is provided on the insulating layer ILD.

For other structures of the display substrate DP2 illustrated in FIG. 7, reference can be made to the illustration of the display substrate DP1 illustrated in FIG. 4, and for the beneficial effects of the display substrate DP2 illustrated in FIG. 7, reference can also be made to the beneficial effects of the display substrate DP1 illustrated in FIG. 4. No further detail will be provided herein. For example, for the thickness comparison between the first separation structure 11 and the first separation structure 12, and for the arrangement of the two second separation structures 12 relative to the encapsulation layer EPS, reference can be made to the illustration of the display substrate DP1 illustrated in FIG. 4 for the display substrate DP2 illustrated in FIG. 7.

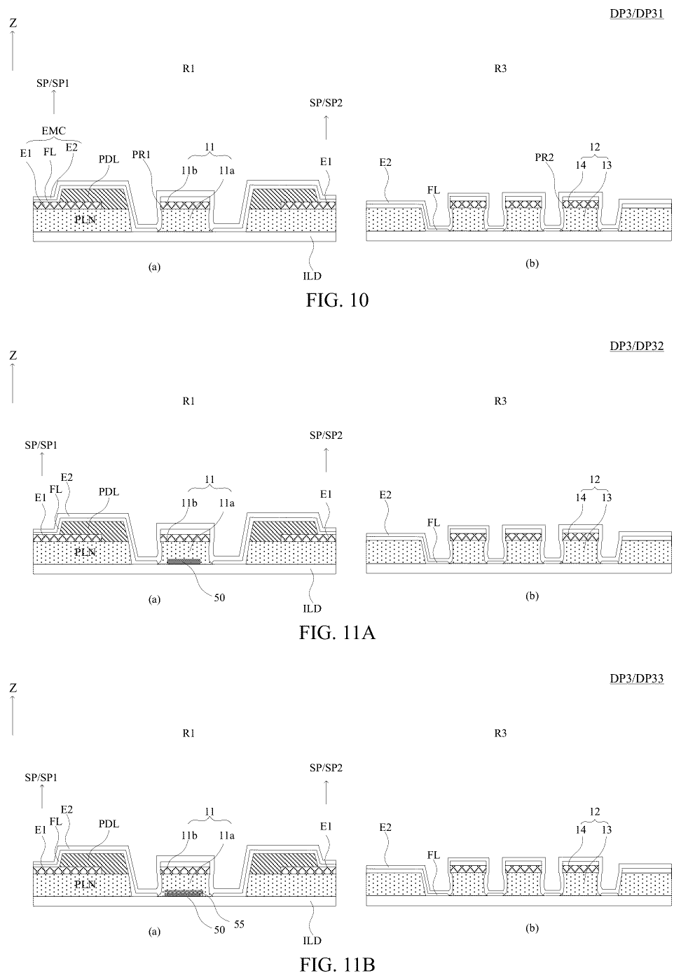

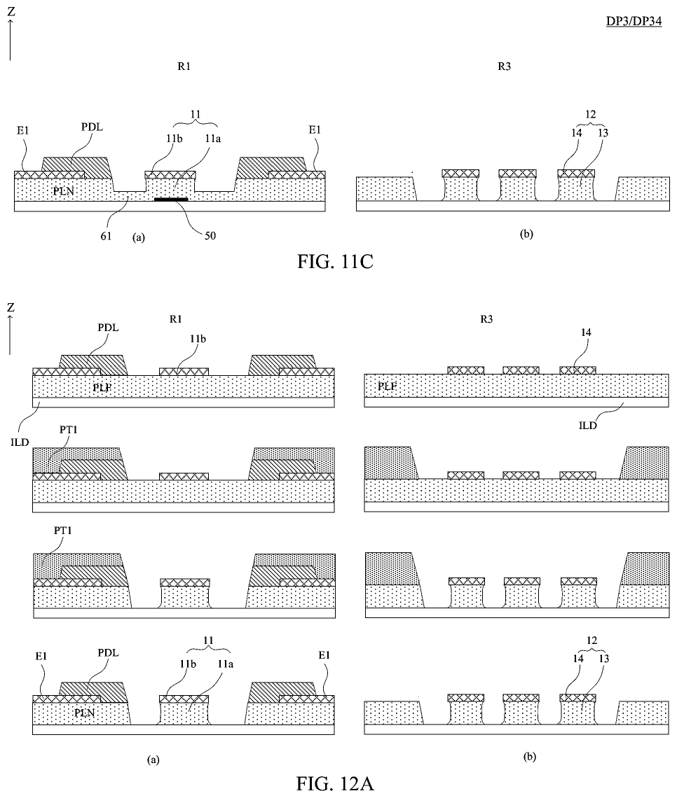

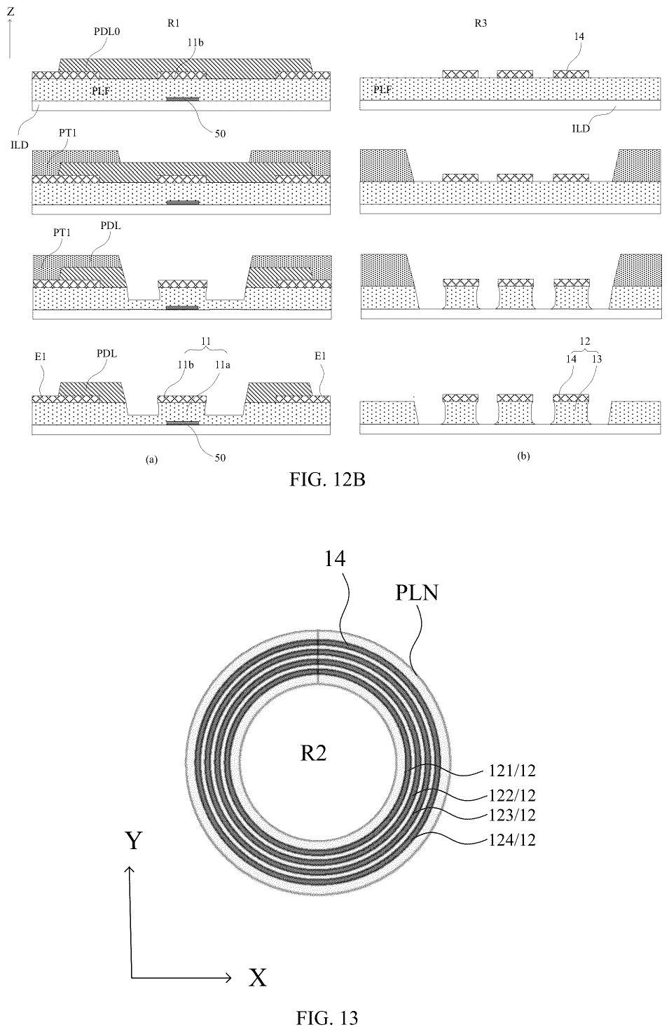

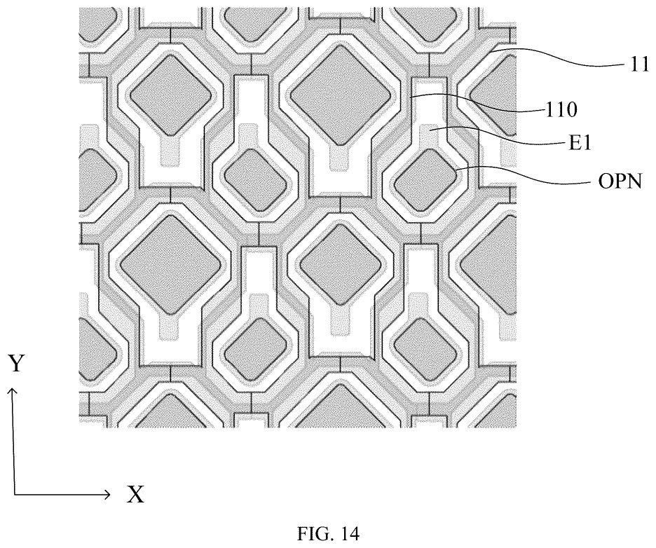

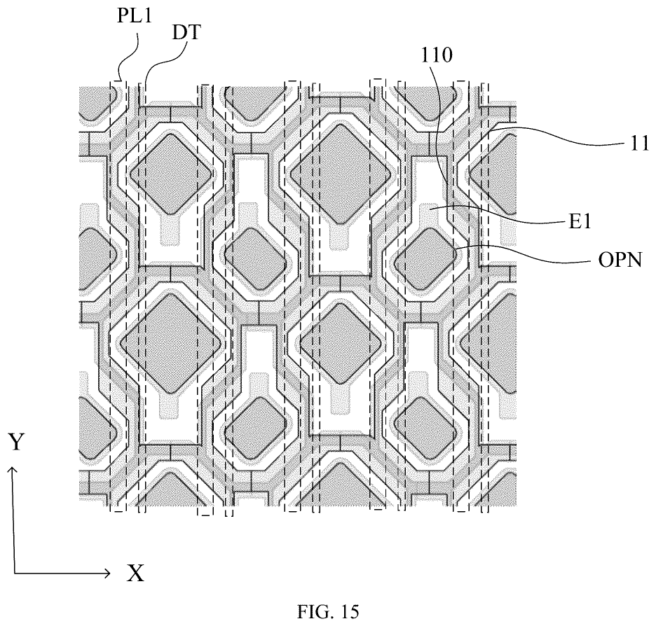

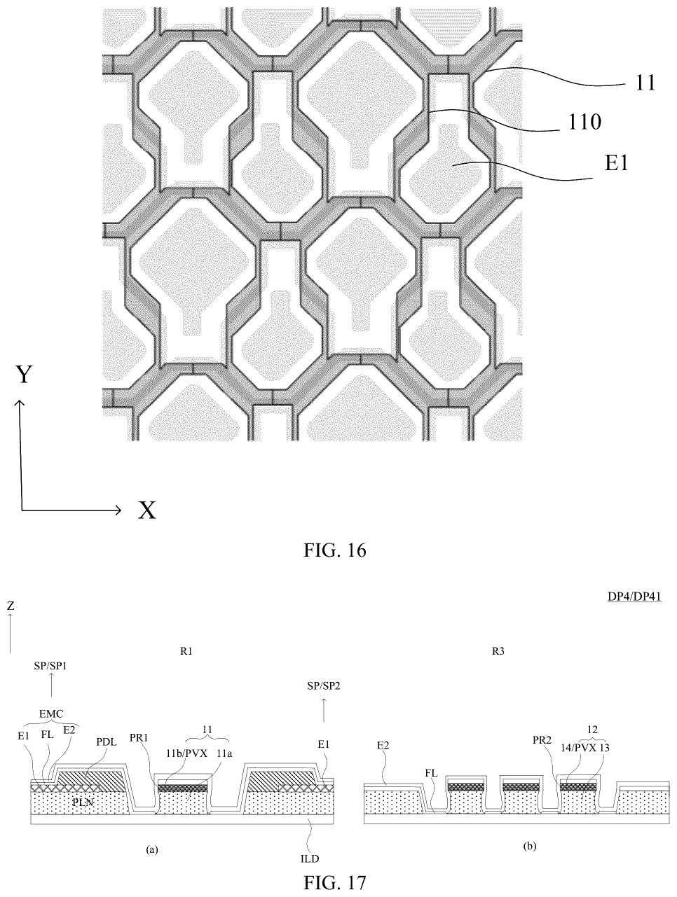

FIG. 10 is a schematic cross-sectional view of a display substrate provided by an embodiment of the present disclosure. FIG. 11A is a schematic cross-sectional view of another display substrate provided by an embodiment of the present disclosure. FIG. 11B is a schematic cross-sectional view of another display substrate provided by an embodiment of the present disclosure. FIG. 11C is a schematic cross-sectional view of another display substrate provided by an embodiment of the present disclosure. FIG. 12A is a flow chart of manufacturing a display substrate provided by an embodiment of the present disclosure. FIG. 12B is a flow chart of manufacturing a display substrate provided by an embodiment of the present disclosure. FIG. 13 is a schematic plan view of a plurality of second separation structures in a display substrate provided by an embodiment of the present disclosure. FIG. 14 is a schematic plan view of a first separation structure and a first electrode in the display substrate illustrated in FIG. 10. FIG. 15 is a schematic plan view of a first separation structure and a conductive structure in the display substrate illustrated in FIG. 11A or FIG. 11B. FIG. 16 is a schematic plan view of a first separation structure in the display substrate illustrated in FIG. 10.

As illustrated in FIG. 10, FIG. 11A, and FIG. 11B, the display substrate DP3 includes a first separation structure 11 and a second separation structure 12. The first separation structure 11 is located in the display region R1 and between adjacent sub-pixels SP. The second separation structure 12 is located in the frame region R3.

As illustrated in FIG. 10, FIG. 11A, and FIG. 11B, the first separation structure 11 includes a first separation part 11a and a second separation part 11b, the first separation part 11a is located in the same layer as the planarization layer PLN and is made of an organic material, and the second separation part 11b is located in the same layer as the first electrode E1 and is made of a conductive material.

As illustrated in FIG. 10, FIG. 11A, and FIG. 11B, the second separation structure 12 includes a third separation part 13 and a fourth separation part 14, the third separation part 13 is located in the same layer as the planarization layer PLN and is made of an organic material, and the fourth separation part 14 is located in the same layer as the first electrode E1 and is made of a conductive material.

As illustrated in FIG. 10, FIG. 11A, and FIG. 11B, the thickness of the first separation part 11a is greater than the thickness of the second separation part 11b, and the thickness of the third separation part 13 is greater than the thickness of the fourth separation part 14.

As illustrated in FIG. 10, FIG. 11A, and FIG. 11B, the light-emitting functional layer FL is disconnected at the first separation structure 11 so as to avoid or reduce crosstalk during luminescence; the light-emitting functional layer FL is disconnected at the second pseparation structure 12, so as to prevent the water and oxygen around the hole from entering the display region R1 along the light-emitting material and improve the service life of the light-emitting element.

As illustrated in FIG. 10, FIG. 11A, and FIG. 11B, the second electrode E2 is continuous at various positions without being disconnected, so that the second electrode E2 has a small resistance, thus improving the uniformity of luminescence of the display substrate.

For example, the patterning process can also be adjusted so that the second electrode E2 is separated at the second separation structure 12 to further improve the encapsulation effect. In this case, the second electrode E2 is disconnected at the second separation structure 12 and is not disconnected at the first separation structure 11, that is, the second electrode E2 is continuous at the first separation structure 11.

For example, the second electrode E2 may be disconnected at the first separation structure 11 by adjusting the shape or size of the first separation part 11a, and the second electrode E2 may be disconnected at the second separation structure 12 by adjusting the shape or size of the third separation part 13. In the case where the second electrode E2 is disconnected at the first separation structure 11, the first separation structure 11 may be provided with a gap, and the second electrodes E2 of adjacent sub-pixels may be connected to each other at the gap, so that the same signal is applied.

Of course, other methods can also be used to improve the encapsulation effect. For example, in order to reduce the risk of disconnection of the second electrode E2 (e.g., cathode) and improve the continuity of the inorganic layer in the encapsulation layer, auxiliary connection electrodes can also be added at the separation structure by adopting a secondary mask so that the second electrodes E2 of different sub-pixels are connected or the light coupling layer CPL (as illustrated in FIG. 1) can also be made conductive. That is, the second electrodes E2 of different sub-pixels are connected through the conductive light coupling layer CPL. For example, the inorganic layers in the encapsulation layer are fabricated by chemical vapor deposition (CVD).

For example, as illustrated in FIG. 11A and FIG. 11B, compared with the display substrate DP31 illustrated in FIG. 10, the display substrate DP32 or the display substrate DP33 further includes a conductive structure 50, and the orthographic projection of the conductive structure 50 on the base substrate BS overlaps the orthographic projection of the first separation structure 11 on the base substrate BS.

As illustrated in FIG. 11B, the protective layer 55 covers the conductive structure 50 to prevent the exposed conductive structure 50 from causing signal short circuit. For example, the protective layer 55 can be made of an inorganic insulating material. For example, the material of the protective layer 55 may be the same as that of the passivation layer.

As illustrated in FIG. 10, FIG. 11A, and FIG. 11B, for the first separation structure 11, the second separation part 11b has a protruding part PR1, and the protruding part PR1 protrudes relative to the first separation part 11a, so that the light-emitting functional layer FL is disconnected at the protruding part PR1. For example, the protruding part PR1 protrudes relative to the middle retracted poriton of the first separation part 11a.

As illustrated in FIG. 10, FIG. 11A, and FIG. 11B, the area of the orthographic projection of the first separation part 11a on the base substrate BS gradually decreases and then gradually increases.

As illustrated in FIG. 10, FIG. 11A, and FIG. 11B, for the second separation structure 12, the fourth separation part 14 has a protruding part PR2, and the protruding part PR2 protrudes relative to the third separation part 13, so that the light-emitting functional layer FL is disconnected at the protruding part. For example, the protruding part PR2 protrudes relative to the middle retracted portion of the third separation part 13.

As illustrated in FIG. 10, FIG. 11A, and FIG. 11B, the area of the orthographic projection of the third separation part 13 on the base substrate BS gradually decreases and then gradually increases.

As illustrated in FIG. 11C, in the display region of the display substrate DP34, a connection part 61 is provided between the first separation part 11a and the planarization layer PLN, and the planarization layer PLN and the first separation part 11a are connected through the connection part 61. The thickness of the connection part 61 is smaller than the thickness of the planarization layer PLN, and the thickness of the connection part 61 is smaller than the thickness of the first separation part 11a. In some embodiments, the thickness of the planarization layer PLN is equal to the thickness of the first separation part 11a. For example, the planarization layer PLN, the first separation part 11a, and the connection part 61 are of an integral structure. Therefore, the space above the conductive structure 50 can be covered by many planarization materials to prevent signal short circuit.

As illustrated in FIG. 12A, the manufacturing method of the display substrate includes the following steps.

Step S11, forming a planarization film PLF on an insulating layer ILD; forming a first electrode E1, a second separation part 11b, and a fourth separation part 14 on the planarization film PLF; and forming a pixel-defining pattern PDL.

Step S12, forming a photoresist pattern PT1.

Step S13, patterning the planarization film PLF by using the photoresist pattern PT1 as a mask.

Step S14, stripping the photoresist pattern PT1 to form a first separation structure 11 and a second separation structure 12.

In step S13, patterning the planarization film PLF includes a dry etching process.

Compared with the manufacturing method of the display substrate illustrated in FIG. 12A, in the manufacturing method of the display substrate illustrated in FIG. 12B, the area where the first separation structure 11 is located is covered with the pixel-defining intermediate pattern PDLO. Upon dry etching, in the area where the first separation structure 11 is located, the pixel-defining intermediate pattern PDLO is first etched and then the planarization film PLF is etched, so that when the etching process is completed, the planarization layer PLN still remains above the conductive structure 50, thus preventing the conductive structure 50 from being exposed so as to avoid signal short circuit.

As illustrated in FIG. 13, the display substrate includes four second separation structures 12. FIG. 13 illustrates a second separation structure 121, a second separation structure 122, a second separation structure 123, and a second separation structure 124. The number of the second separation structures 12 included in the display substrate is not limited to what is illustrated in the figure.

For example, as illustrated in FIG. 15, the conductive structure 50 includes a data line DT or a power line PL1. The data line DT extends along the direction Y, and the power line PL1 extends along the direction Y. The data lines DT or the power lines PL1 are arranged along the direction X.

FIG. 16 illustrates the first electrode E1 and the first separation structure 11. As illustrated in FIG. 14 to FIG. 16, the first separation structure 11 is in the shape of a mesh and includes a plurality of openings 110, and the first electrode E1 is located in the opening 110. Each opening 110 may correspond to a sub-pixel. As illustrated in FIG. 14, the first separation structure 11 surrounds the light-emitting region R0. In a plan view, the first separation structure 11 is located outside the light-emitting region R0 and is spaced from the light-emitting region R0.

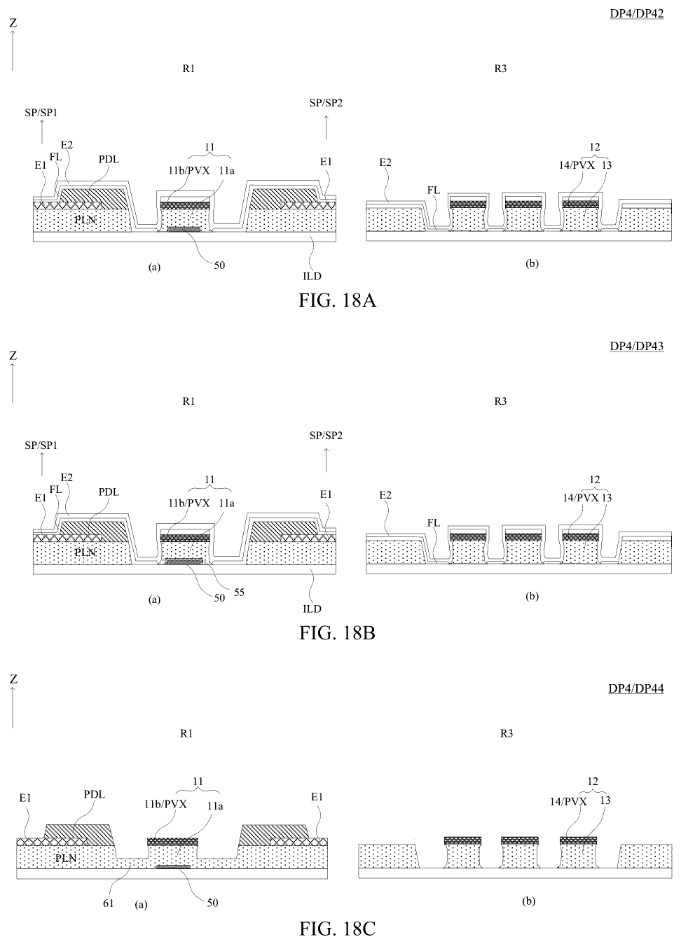

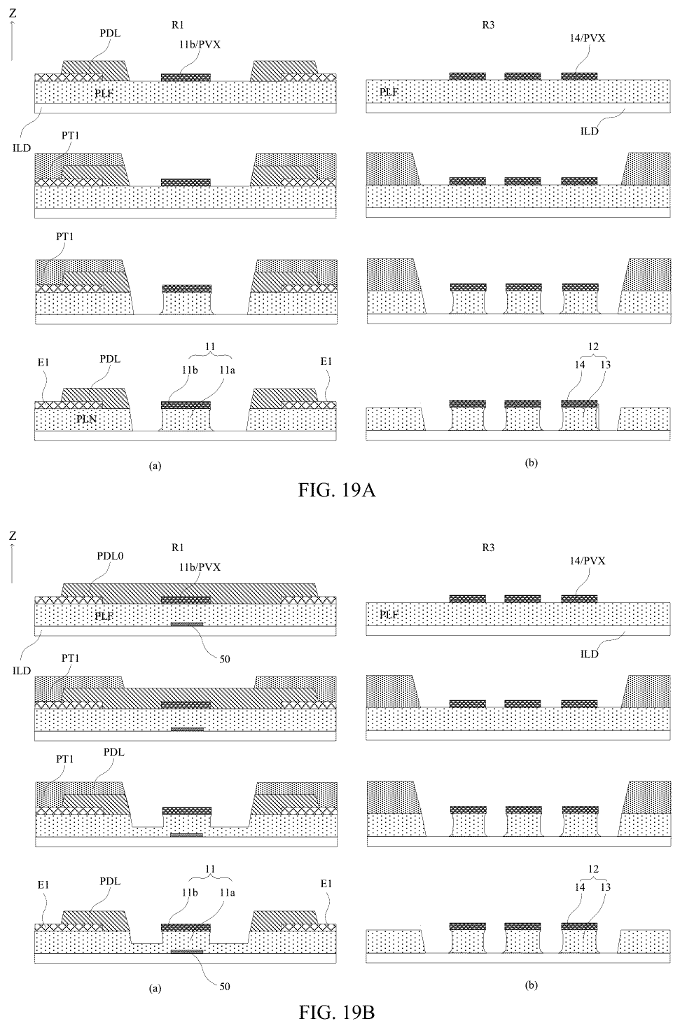

FIG. 17 is a schematic cross-sectional view of a display substrate provided by an embodiment of the present disclosure. FIG. 18A is a schematic cross-sectional view of another display substrate provided by an embodiment of the present disclosure. FIG. 18B is a schematic cross-sectional view of another display substrate provided by an embodiment of the present disclosure. FIG. 18C is a schematic cross-sectional view of another display substrate provided by an embodiment of the present disclosure. FIG. 19A is a flow chart of manufacturing a display substrate provided by an embodiment of the present disclosure. FIG. 19B is a flow chart of manufacturing a display substrate provided by an embodiment of the present disclosure.

FIG. 17, and FIG. 18A to FIG. 18C illustrate a display substrate DP4, FIG. 17 illustrates a display substrate DP41, FIG. 18A illustrates a display substrate DP42, FIG. 18B illustrates a display substrate DP43, and FIG. 18C illustrates a display substrate DP44.

The display substrate DP41 illustrated in FIG. 17 differs from the display substrate DP31 illustrated in FIG. 10 in that the second separation part 11b of the first separation structure 11 is an inorganic insulating material, the fourth separation part 14 of the second separation structure 12 is an inorganic insulating material, and both the second separation part 11b and the fourth separation part 14 are located in the passivation layer PVX.

The display substrate DP42 illustrated in FIG. 18A differs from the display substrate DP32 illustrated in FIG. 11A in that the second separation part 11b of the first separation structure 11 is an inorganic insulating material, the fourth separation part 14 of the second separation structure 12 is an inorganic insulating material, and both the second separation part 11b and the fourth separation part 14 are located in the passivation layer PVX.

The display substrate DP43 illustrated in FIG. 18B differs from the display substrate DP33 illustrated in FIG. 11B in that the second separation part 11b of the first separation structure 11 is an inorganic insulating material, the fourth separation part 14 of the second separation structure 12 is an inorganic insulating material, and both the second separation part 11b and the fourth separation part 14 are located in the passivation layer PVX.

The display substrate DP44 illustrated in FIG. 18C differs from the display substrate DP34 illustrated in FIG. 11C in that the second separation part 11b of the first separation structure 11 is an inorganic insulating material, the fourth separation part 14 of the second separation structure 12 is an inorganic insulating material, and both the second separation part 11b and the fourth separation part 14 are located in the passivation layer PVX.

In FIG. 19A, a passivation layer PVX, a first electrode E1, and a pixel-defining pattern PDL are sequentially formed on the planarization film PLF. The passivation layer PVX includes a second separation part 11b and a fourth separation part 14. For other steps, reference may be made to the illustration of FIG. 12A.

In FIG. 19B, a passivation layer PVX, a first electrode E1, and a pixel-defining pattern PDL are sequentially formed on the planarization film PLF. The passivation layer PVX includes a second separation part 11b and a fourth separation part 14. For other steps, reference may be made to the illustration of FIG. 12B.

For example, for the plan view of the second separation structure 12 in the display substrate DP4 illustrated in FIG. 17, and FIG. 18A to FIG. 18C, reference can be made to FIG. 13. For the plan view of the first separation structure 11 in the display substrate DP4, reference can also be made to FIG. 14 to FIG. 16.

For example, in the display substrate DP4 illustrated in FIG. 17, and FIG. 18A to FIG. 18C, the first separation structure 11 is made of an insulating material, the second separation structure 12 is made of an insulating material, the first separation part 11a and the third separation part 13 are made of an organic insulating material, and the second separation part 11b and the fourth separation part 14 are made of an inorganic insulating material. For example, the inorganic insulating material includes SiOx, SiNy, or SiOxNy. For example, the organic insulating material includes a resin, but is not limited thereto. For example, the organic insulating material includes one of acrylic, polyethylene terephthalate, polyimide, polyamide, polycarbonate, epoxy resin, and the like, or a combination thereof. Of course, in other embodiments, the second separation part 11b and the fourth separation part 14 may also be made of a metal material or conductive metal oxide.

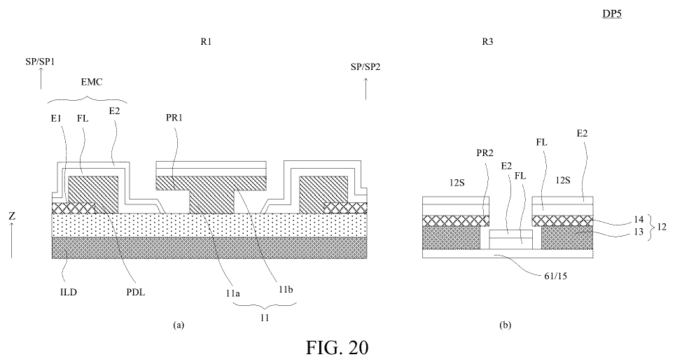

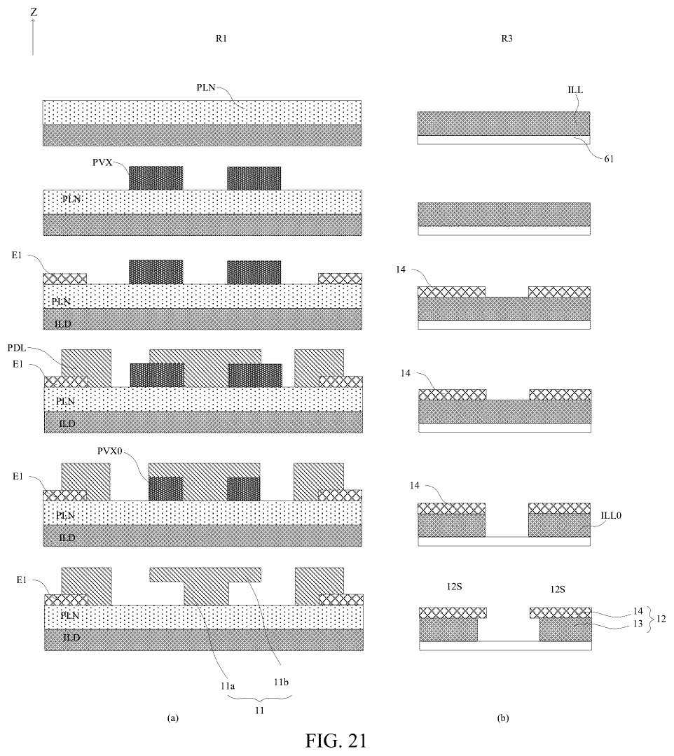

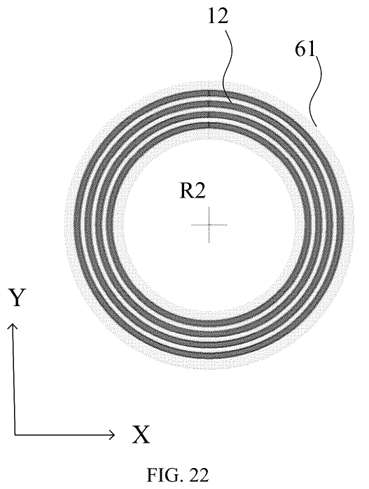

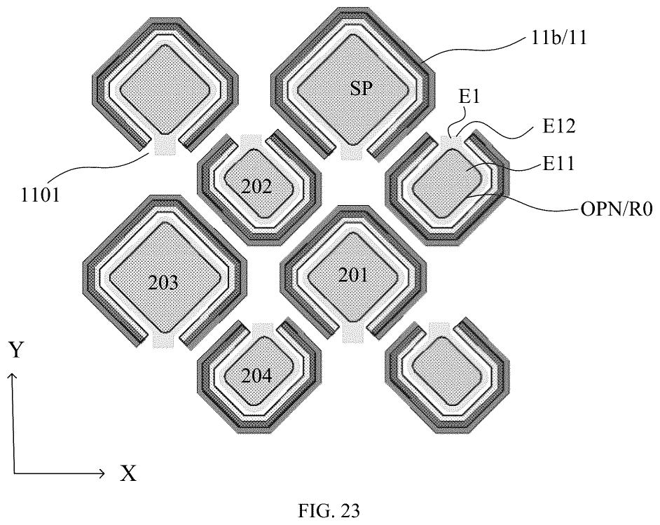

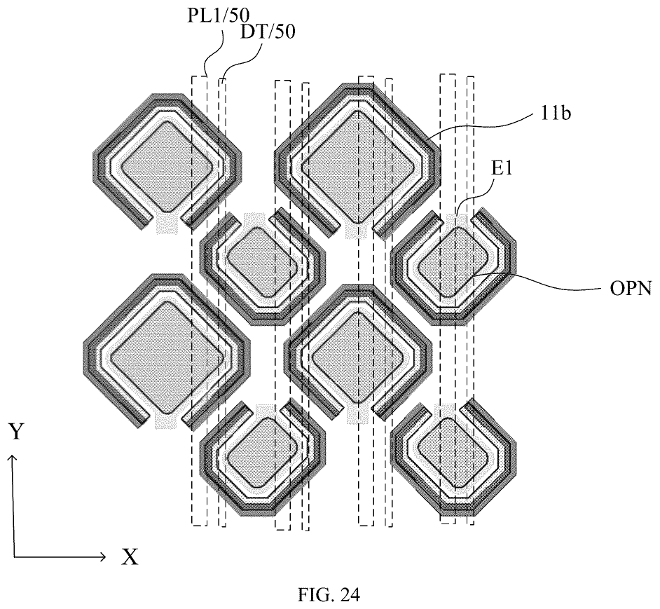

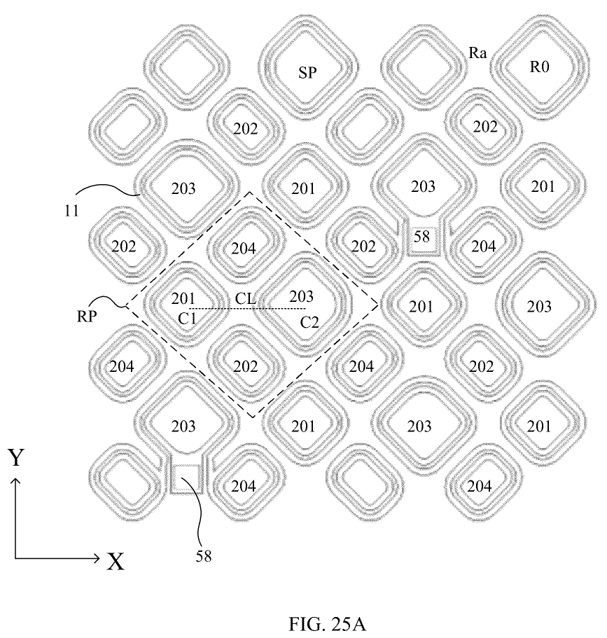

FIG. 20 is a schematic cross-sectional view of a display substrate provided by an embodiment of the present disclosure. FIG. 21 is a flow chart of manufacturing the display substrate illustrated in FIG. 20. FIG. 22 is a plan view of a second separation structure in a frame region of the display substrate illustrated in FIG. 20. FIG. 23 is a plan view of a first separation structure in a display region of a display substrate provided by an embodiment of the present disclosure. FIG. 24 is a plan view of a first separation structure in a display region of a display substrate provided by an embodiment of the present disclosure. FIG. 23 and FIG. 24 may be plan views of a first separation structure in the display substrate illustrated in FIG. 20.

As illustrated in FIG. 20, the first separation structure 11 and the second separation structure 12 are different. The materials and structures of the first separation structure 11 and the second separation structure 12 are different.

As illustrated in FIG. 20, in the first separation structure 11, the first separation part 11a and the second separation part 11b are both made of organic insulating materials, and the first separation part 11a and the second separation part 11b are of an integral structure. The first separation part 11a and the second separation part 11b are located in the same layer as the pixel-defining pattern PDL.

As illustrated in FIG. 20, in the second separation structure 12, the third separation part 13 is located in the same layer as the insulating layer ILD and is made of an inorganic insulating material, and the fourth separation part 14 is located in the same layer as the first electrode E1 and is made of a conductive material.

For example, as illustrated in FIG. 20, the light-emitting functional layer FL is separated by the first separation structure 11, and includes a portion located on the first separation structure 11 and another portion spaced from the portion located on the first separation structure 11. Because the light-emitting functional layer FL is separated by the first separation structure 11, crosstalk is avoided when the display substrate emits light.

For example, as illustrated in FIG. 20, the second electrode E2 is separated at the position where the first separation structure 11 is provided, thus forming a portion on the first separation structure 11 and another portion spaced from the portion on the first separation structure 11.

For example, as illustrated in FIG. 20, the light-emitting functional layer FL is separated by the second separation structure 12, and includes a portion located on the second separation structure 12 and another portion separated from the portion located on the second separation structure 12, so as to prevent water and oxygen from entering the display region along the light-emitting material around the hole region, thereby improving the service life of the light-emitting element.

For example, as illustrated in FIG. 20, the second electrode E2 is separated at the position where the second separation structure 12 is provided, thus forming a portion located on the second separation structure 12 and another portion separated from the portion located on the second separation structure 12.

As illustrated in FIG. 21, the manufacturing method of the display substrate DP5 includes the following steps.

Step 101, sequentially forming a conductive part 61, an insulating thin film ILL, and a planarization layer PLN.

Step 102, forming a passivation layer PVX.

Step 103, forming a first electrode E1 and a fourth separation part 14.

Step 104, forming a pixel-defining pattern PDL.

Step 105, dry etching the passivation layer PVX and the insulating thin film ILL respectively by using the pixel-defining pattern PDL and the fourth separation part 14 as masks to form an intermediate passivation layer PVX0 and an intermediate insulating layer ILLO.

Step 106, wet etching the intermediate passivation layer PVX0 and the intermediate insulating layer ILLO to form a first separation structure 11 and a second separation structure 12.

For example, the conductive part 61 may be located in the same layer as the gate electrode of the thin film transistor.

For example, as illustrated in FIG. 20 and FIG. 21, the second separation structure includes two sub-separation structures 12S, and the protruding parts PR2 of the two sub-separation structures 12S are oppositely arranged.

The display substrate illustrated in FIG. 20 can effectively realize the compatibility of the first separation structure and the second separation structure with the tandem process.

The first separation structure 11 and the second separation structure 12 in the display substrate DP5 illustrated in FIG. 20 include portions formed by simultaneous etching, and have good process compatibility.

FIG. 22 illustrates four second separation structures 12. The second separation structure 12 is annularly arranged around the hole region R2.

As illustrated in FIG. 20 and FIG. 22, the orthographic projection of the second separation structure 12 on the base substrate overlaps the orthographic projection of the conductive part 61 on the base substrate. For further example, the orthographic projection of the second separation structure 12 on the base substrate completely falls within the orthographic projection of the conductive part 61 on the base substrate.

As illustrated in FIG. 23, the first separation structure 11 is disposed on the outer side of the light-emitting region R0 of the light-emitting element, and the first separation structure 11 has a gap 1101. Thus, the first separation structure 11 is a ring structure with the gap 1101.

For example, because the gap 1101 is provided, the light-emitting functional layers of adjacent sub-pixels are continuous at the gap 1101, and the second electrode of the light-emitting element is continuous at the gap 1101.

As illustrated in FIG. 23, the first electrode E1 has a main body part E11 and a connecting part E12, the orthographic projection of the main body part E11 on the base substrate overlaps the orthographic projection of the light-emitting region R0 on the base substrate, and the connecting part E12 is configured to be connected to other components. For example, the connecting part E12 is connected to the thin film transistor T0. Referring to FIG. 4 and FIG. 23, the orthographic projection of the connecting part E12 on the base substrate overlaps the orthographic projection of the via hole VO on the base substrate. As illustrated in FIG. 23, the connecting part E12 is located at the gap 1101.

As illustrated in FIG. 23, the display substrate includes a first sub-pixel 201, a second sub-pixel 202, a third sub-pixel 203, and a fourth sub-pixel 204. For example, one of the first sub-pixel 201 and the third sub-pixel 203 is a blue sub-pixel, the other of the first sub-pixel 201 and the third sub-pixel 203 is a red sub-pixel, and the second sub-pixel 202 and the fourth sub-pixel 204 may be sub-pixels of the same color, e.g., both are green sub-pixels. The light-emitting colors of the first sub-pixel 201, the second sub-pixel 202, the third sub-pixel 203, and the fourth sub-pixel 204 can be set as required.

As illustrated in FIG. 23, the first sub-pixel 201, the second sub-pixel 202, the third sub-pixel 203, and the fourth sub-pixel 204 constitute a repeating unit, the second sub-pixel 202 and the fourth sub-pixel 204 are located on both sides of the connecting line connecting the centers of the first sub-pixel 201 and the third sub-pixel 203, the opening of the first separation structure 11 outside the second sub-pixel 202 and the opening of the first separation structure 11 outside the fourth sub-pixel 204 face the same direction, and the opening of the first separation structure 11 outside the first sub-pixel 201 and the opening of the first separation structure 11 outside the third sub-pixel 203 face the same direction.

As illustrated in FIG. 23, the openings of the first separation structure 11 outside the second sub-pixel 202 and the first separation structure 11 outside the fourth sub-pixel 204 face different directions from the openings of the first separation structure 11 outside the first sub-pixel 201 and the first separation structure 11 outside the fourth sub-pixel 203. As illustrated in FIG. 23, the openings of the first separation structure 11 outside the second sub-pixel 202 and the first separation structure 11 outside the fourth sub-pixel 204 face opposite directions from the openings of the first separation structure 11 outside the first sub-pixel 201 and the first separation structure 11 outside the fourth sub-pixel 203.

As illustrated in FIG. 23, the openings of the first separation structure 11 outside the second sub-pixel 202 and the first separation structure 11 outside the fourth sub-pixel 204 both face upward, and the openings of the first separation structure 11 outside the first sub-pixel 201 and the first separation structure 11 outside the third sub-pixel 203 both face downward.

For example, as illustrated in FIG. 23, the first separation structure 11 is located at one corner of the light-emitting region R0. For example, the light-emitting region R0 includes four corners, and the first separation structure 11 is provided outside each of the three corners of the light-emitting region R0. For example, the orthographic projection of the first separation structure 11 on the base substrate BS surrounds at least one half of the orthographic projection of the light-emitting region R0 on the base substrate BS. For example, the orthographic projection of the first separation structure 11 on the base substrate BS surrounds at least three quarters of the orthographic projection of the light-emitting region R0 on the base substrate BS.

For example, as illustrated in FIG. 24, the orthographic projection of the conductive structure 50 on the base substrate BS overlaps the orthographic projection of the first separation structure 11 on the base substrate BS. The conductive structure 50 includes a data line DT or a power line PL1. The data line DT extends along the direction Y, and the power line PL1 extends along the direction Y. The data lines DT or the power lines PL1 are arranged along the direction X.

In an embodiments of the present disclosure, the conductive structure 50 may also be disposed under the first separation structure 11 of another display substrate, and it is no limited to the figure illustrating the conductive structure 50. In addition to being a conductive line such as a power line or a data line, the conductive structure 50 may also be a structure such as another line or an electrode plate of a capacitor.

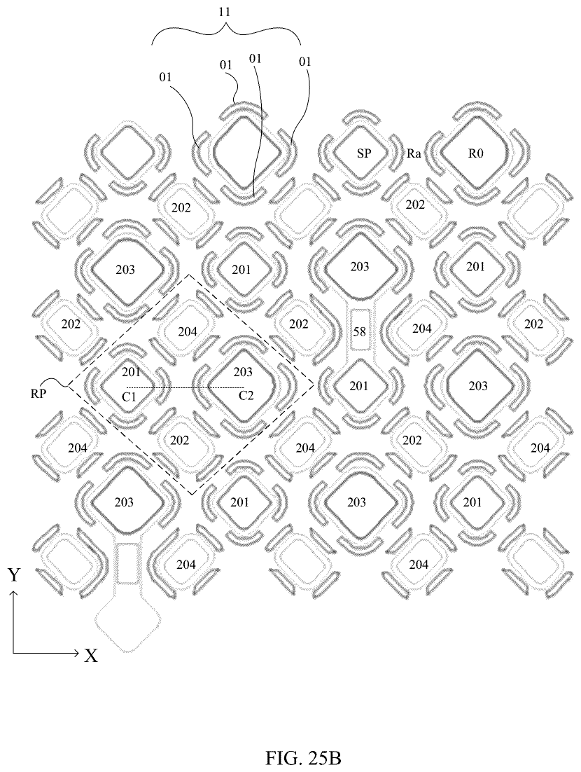

FIG. 25A is a schematic plan view of another display substrate provided by an embodiment of the present disclosure. According to the display substrate provided by the embodiments of the present disclosure, as illustrated in FIG. 25A, the first separation structure 11 is ring-shaped, and the first separation structure 11 is arranged in a shape of a ring to surround the light-emitting region R0. The second electrode E2 is continuous at the protruding part of the first separation structure 11 so as to facilitate signal transmission on the second electrodes E2 of different sub-pixels. The cross-sectional view of the first separation structure 11 is as illustrated above.

As illustrated in FIG. 25A, the light-emitting region R0 of each sub-pixel SP is surrounded by one first separation structure 11.

FIG. 25B is a schematic plan view of another display substrate provided by an embodiment of the present disclosure. According to the display substrate provided by the embodiments of the present disclosure, as illustrated in FIG. 25B, the first separation structure 11 includes at least one separation structure 01, and the orthographic projection of at least one separation structure 01 on the base substrate BS at least surrounds one half of the orthographic projection of the light-emitting region R0 on the substrate substrate BS.

As illustrated in FIG. 25B, the light-emitting region R0 of each sub-pixel SP is surrounded by three or four separation sub-structures 01. The number of separation structures 01 can be set as required.

As illustrated in FIG. 25A and FIG. 25B, the display substrate includes a first sub-pixel 201, a second sub-pixel 202, a third sub-pixel 203, and a fourth sub-pixel 204. For example, one of the first sub-pixel 201 and the third sub-pixel 203 is a blue sub-pixel, the other of the first sub-pixel 201 and the third sub-pixel 203 is a red sub-pixel, and the second sub-pixel 202 and the fourth sub-pixel 204 may be sub-pixels of the same color, e.g., both are green sub-pixels. The light-emitting colors of the first sub-pixel 201, the second sub-pixel 202, the third sub-pixel 203, and the fourth sub-pixel 204 can be set as required.

For example, as illustrated in FIG. 25A and FIG. 25B, one first sub-pixel 201, one second sub-pixel 202, one third sub-pixel 203, and one fourth sub-pixel 204 constitute a repeating unit RP, and in a repeating unit RP, the second sub-pixel 202 and the fourth sub-pixel 204 are located on both sides of the connecting line CL connecting the centers of the first sub-pixel 201 and the third sub-pixel 203. FIG. 25A and FIG. 25B illustrate the center C1 of the first sub-pixel 201 and the center C2 of the third sub-pixel 203. Correspondingly, the first sub-pixel 201 and the third sub-pixel 203 are also respectively arranged on both sides of the connecting line connecting the centers of the second sub-pixel 202 and the fourth sub-pixel 204.

For example, in other embodiments, only one separation structure is provided between two adjacent sub-pixels, so that the width of the spacing between two adjacent sub-pixels can be reduced so as to increase the pixel density.

FIG. 25A and FIG. 25B also illustrate a spacer 58. The spacer 58 is configured to support a fine metal mask when forming a light-emitting layer.

As illustrated, the spacer 58 is within the area surrounded by the first sub-pixel 201, the second sub-pixel 202, the third sub-pixel 203, and the fourth sub-pixel 204.

As illustrated in FIG. 25B, the spacer 58 is provided between the first sub-pixel 201 and the third sub-pixel 203 which are arranged in the second direction Y.

Some figures illustrate the direction X and the direction Y. The direction X intersects the direction Y. For example, the direction X is perpendicular to the direction Y. Both the direction X and the direction Y are directions parallel to the main surface of the base substrate. For example, the direction Z is perpendicular to the direction X and is perpendicular to the direction Y.

In addition to the forms of the first separation structure 11 illustrated in FIG. 14 to FIG. 16, FIG. 23, FIG. 24, FIG. 25A, and FIG. 25B, the first separation structure 11 may also be in any other suitable form.

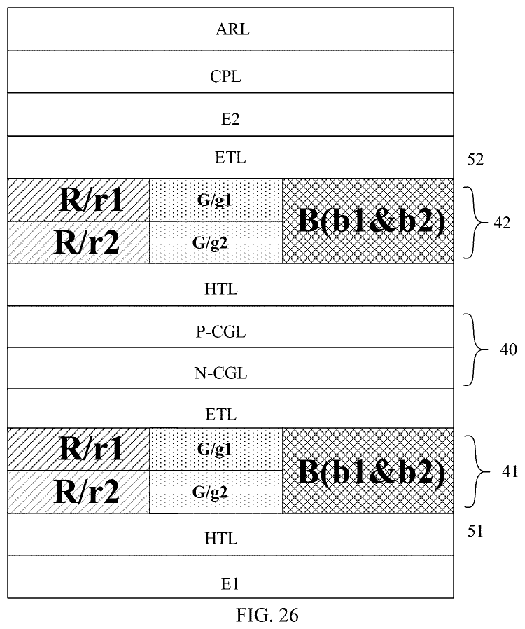

FIG. 26 is a schematic diagram of light-emitting elements in a display substrate provided by an embodiment of the present disclosure. As illustrated in FIG. 26, according to the display substrate provided by the embodiments of the present disclosure, the light-emitting functional layer FL includes a charge generation layer 40, a first light-emitting layer 41, and a second light-emitting layer 42 which are stacked, the first light-emitting layer 41 is located between the first electrode E1 and the charge generation layer 40, the second light-emitting layer 42 is located between the second electrode E2 and the charge generation layer 40, and the charge generation layer 40 is disconnected at the protruding part PR1. Because the charge generation layer 40 is disconnected at the first separation structure 11, the propagation path of the charge is long and the resistance of the charge generation layer in the light-emitting functional layer is large, thus effectively avoiding crosstalk between adjacent sub-pixels.

For example, in some embodiments, in addition to the disconnection of the charge generation layer 40 at the protruding part PR1, the sub-functional layer between the charge generation layer 40 and the first electrode E1 is also disconnected at the protruding part PR1, and the sub-functional layer between the charge generation layer 40 and the second electrode E2 is not disconnected at the protruding part PR1. In other embodiments, in addition to the disconnection of the charge generation layer 40 at the protruding part PR1, the sub-functional layer between the charge generation layer 40 and the first electrode E1 is also disconnected at the protruding part PR1, and the sub-functional layer between the charge generation layer 40 and the second electrode E2 is also disconnected at the protruding part PR1; and in this case, each sub-functional layer of the light-emitting functional layer FL is disconnected at the protruding part PR1.

As illustrated in FIG. 26, according to the display substrate provided by the embodiments of the present disclosure, the light-emitting functional layer FL further includes a first charge transport layer 51 located between the first electrode E1 and the first light-emitting layer 41 and a second charge transport layer 52 located between the first light-emitting layer 41 and the charge generation layer 40, and the first charge transport layer 51 and the second charge transport layer 52 are respectively disconnected at the protruding part PR1.

As illustrated in FIG. 26, the first charge transport layer 51 is a hole transport layer HTL, and the second charge transport layer 52 is an electron transport layer ETL. For other structures, reference may be made to the illustration of FIG. 1.

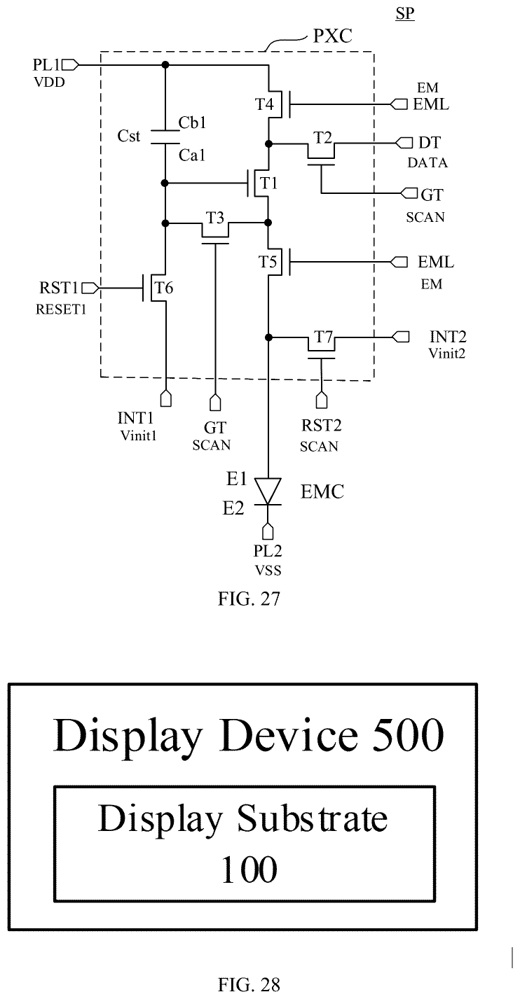

FIG. 27 is a schematic diagram of a pixel circuit and a light-emitting element in a display substrate. FIG. 27 is illustrated by taking the pixel circuit of 7TIC as an example. It should be noted that the pixel circuit is not limited to what is illustrated in FIG. 27, and can be set as required. As illustrated in FIG. 27, the display substrate includes a sub-pixel SP, and the sub-pixel includes a pixel circuit PXC and a light-emitting element EMC. The light-emitting element EMC includes a first electrode E1, a second electrode E2, and a light-emitting functional layer located between the first electrode E1 and the second electrode E2. The pixel circuit PXC includes a transistor and a storage capacitor Cst. For example, the transistor includes transistors T1-T7, and the storage capacitor Cst includes an electrode plate Cal and an electrode plate Cb1. FIG. 27 also illustrates the gate line GT providing the scan signal SCAN, the data line DT providing the data signal DATA, the light-emitting control signal line EML providing the light-emitting control signal EM, the power line PL1 providing the power supply voltage VDD, the power line PL2 providing the power supply voltage VSS, the reset control signal line RST1 providing the reset signal RESET, the reset control signal line RST2 providing the scan signal SCAN, the initialization signal line INT1 providing the initialization signal Vinit1, and the initialization signal line INT2 providing the initialization signal Vinit2.

For example, as illustrated in FIG. 27, the transistor T1 is a driving transistor, the transistor T2 is a data writing transistor, the transistor T3 is a threshold compensation transistor, the transistor T4 is a light-emitting control transistor, the transistor T5 is a light-emitting control transistor, the transistor T6 is a reset control transistor, and the transistor T7 is a reset control transistor.

For example, as illustrated in FIG. 13 and FIG. 22, the second separation structure 12 is ring-shaped so as to surround the hole region R2.

For example, as illustrated in FIG. 4, FIG. 5B, FIG. 7, and FIG. 20, the second electrode E2 is disconnected at the protruding part PR2 of the second separation structure 12.

For example, as illustrated in FIG. 4, FIG. 5A, FIG. 10, FIG. 11A, FIG. 11B, FIG. 17, FIG. 18A, FIG. 18B and FIG. 20, the second electrode E2 is continuous at the protruding part PR1.

For example, as illustrated in FIG. 14, the first separation structure 11 is ring-shaped and continuously arranged around the light-emitting region.

For example, as illustrated in FIG. 24, the first separation structure 11 has a gap 1101.

For example, as illustrated in FIG. 4 and FIG. 7, the dimension of the first separation part 11a in the direction perpendicular to the base substrate BS is smaller than the dimension of the second separation part 11b in the direction perpendicular to the base substrate BS.

For example, as illustrated in FIG. 10, FIG. 11A to FIG. 11C, FIG. 17, FIG. 18A to FIG. 18C, and FIG. 20, the dimension of the first separation part 11a in the direction perpendicular to the base substrate BS is greater than the dimension of the second separation part 11b in the direction perpendicular to the base substrate BS.

For example, as illustrated in FIG. 4 and FIG. 7, the dimension of the first separation part 11a in the direction perpendicular to the base substrate BS is smaller than the dimension of the third separation part 13 in the direction perpendicular to the base substrate BS.

For example, as illustrated in FIG. 4, FIG. 7, FIG. 10, FIG. 11A to FIG. 11C, FIG. 17, and FIG. 18A to FIG. 18C, the second separation part 11b and the fourth separation part 14 are located in the same layer.

For example, as illustrated in FIG. 20, the second separation part 11b and the fourth separation part 14 are located in different layers and made of different materials.

For example, as illustrated in FIG. 10, FIG. 11A to FIG. 11C, FIG. 17, and FIG. 18A to FIG. 18C, the first separation structure 11 and the second separation structure 12 have the same layer structure.

For example, as illustrated in FIG. 4, FIG. 7, and FIG. 20, the first separation structure 11 and the second separation structure 12 have different layer structures.

For example, as illustrated in FIG. 4 and FIG. 7, a count of film layers included in the first separation part 11a is less than or equal to a count of film layers included in the third separation part 13.

For example, as illustrated in FIG. 4, the material of the first separation structure 11 includes a conductive material, and the material of the second separation structure 12 includes a conductive material. For example, the conductive material includes a metal and a conductive metal oxide.

For example, as illustrated in FIG. 7, the material of the first separation structure 11 includes an inorganic insulating material, and the material of the second separation structure 12 includes an inorganic insulating material.

For example, as illustrated in FIG. 10, FIG. 11A to FIG. 11C, FIG. 17, and FIG. 18A to FIG. 18C, the materials of the first separation part 11a and the second separation part 11b are different, the materials of the third separation part 13 and the fourth separation part 14 are different, the materials of the first separation part 11a and the third separation part 13 are the same, and the materials of the second separation part 11b and the fourth separation part 14 are the same.

For example, as illustrated in FIG. 17 and FIG. 18A to FIG. 18C, the materials of the first separation part 11a and the third separation part 13 include organic materials, and the materials of the second separation part 11b and the fourth separation part 14 include inorganic insulating materials.

For example, as illustrated in FIG. 10 and FIG. 11A to FIG. 11C, the materials of the first separation part 11a and the third separation part 13 include organic insulating materials, and the materials of the second separation part 11b and the fourth separation part 14 include conductive materials.

For example, as illustrated in FIG. 20, the material of the first separation part 11a includes an organic insulating material, the material of the second separation part 11b includes an organic insulating material, the material of the third separation part 13 includes an inorganic insulating material, and the material of the fourth separation part 14 includes a conductive material.

For example, as illustrated in FIG. 20, the first separation part 11a and the second separation part 11b are of an integral structure.

For example, as illustrated in FIG. 4, FIG. 7, FIG. 10, FIG. 11A to FIG. 11C, 17, and FIG. 18A to FIG. 18C, the material of the second separation part 11b is different from that of the first separation part 11a.

For example, in the embodiments of the present disclosure, the inorganic insulating material includes SiOx, SiNy, or SiOxNy. For example, the conductive material includes a metal or a conductive metal oxide. For example, the organic insulating material includes one of acrylic, polyethylene terephthalate, polyimide, polyamide, polycarbonate, epoxy resin, and the like, or a combination thereof.

For example, as illustrated in FIG. 20, a plurality of second separation structures 12 are provided, the second separation structure 12 also includes a fifth separation part 15, the material of the fifth separation part 15 includes a conductive material, the fifth separation part 15 of the plurality of second separation structures is of an integral structure, and a plurality of fourth separation parts 14 are sequentially arranged around the hole region R2. The conductive part 61 is the fifth separation part 15.

For example, as illustrated in FIG. 4, FIG. 7, FIG. 10, FIG. 11A to FIG. 11C, FIG. 17, FIG. 18A to FIG. 18C and FIG. 20, the first separation structure 11 is T-shaped.

For example, the second electrode E2 is the cathode of the light-emitting element, and the first electrode E1 is the anode of the light-emitting element. In some embodiments, the display substrate forms a common cathode structure. In the case that the second electrode E2 is a continuous electrode on the entire surface and is not disconnected by a separation structure, the resistance of the second electrode E2 is reduced and signal transmission on the second electrode E2 is facilitated.

For example, in the embodiments of the present disclosure, the first electrodes E1 of different sub-pixels are insulated from each other, the first electrodes E1 of different sub-pixels are arranged independently of each other, and different signals may be applied thereto. The second electrodes E2 of different sub-pixels are connected to each other, and the same signal can be applied thereto.

In the embodiments of the present disclosure, for the second separation structure 12 located in the frame region, illustration of FIG. 4 and FIG. 7 is made by taking as an example that the structures of the second separation structures 12 located on both sides of the barrier dam 17 are the same. In other embodiments, the structures of the second separation structures 12 located on both sides of the barrier dam 17 may also be different. As such, the second electrode E2 is separated on the outer side of the barrier dam 17 (the left side of the barrier dam 17 in the figure) but is not separated on the inner side of the barrier dam 17 (the right side of the barrier dam 17 in the figure); alternatively, the second electrode E2 is not separated on the outer side of the barrier dam 17 (the left side of the barrier dam 17 in the figure) but is separated on the inner side of the barrier dam 17 (the right side of barrier dam 17 in the figure).

According to actual needs, the separation of the second electrode E2 by the first separation structure 11 and the second separation structure 12 can be realized by controlling process conditions or adding processes. Whether the second electrode E2 is separated at the first separation structure 11 or the second separation structure 12 can also be realized by adjusting the process.

For example, as illustrated in FIG. 4 and FIG. 7, the thickness of the first separation structure 11 in the direction perpendicular to the base substrate BS is smaller than the thickness of the planarization layer PLN in the direction perpendicular to the base substrate BS.

For example, as illustrated in FIG. 10, FIG. 11A to FIG. 11C, FIG. 17, and FIG. 18A to FIG. 18C, the maximum thickness of the first separation structure 11 in the direction perpendicular to the base substrate BS is less than the maximum thickness of the planization layer PLN in the direction perpendicular to the base substrate BS.

For example, as illustrated in FIG. 10, FIG. 11A to FIG. 11C, FIG. 17, and FIG. 18A to FIG. 18C, the maximum thickness of the first separation structure 11 in the direction perpendicular to the base substrate BS is less than the maximum thickness of the planization layer PLN in the direction perpendicular to the base substrate BS.

For example, as illustrated in FIG. 20, the maximum thickness of the first separation structure 11 in the direction perpendicular to the base substrate BS is equal to the maximum thickness of the pixel-defining pattern PDL in the direction perpendicular to the base substrate BS.

For example, as illustrated in FIG. 10, FIG. 11A to FIG. 11C, FIG. 17, and FIG. 18A to FIG. 18C, the side surface of the first separation part 11a is arc-shaped and has a gentle transition, thus facilitating arrangement of the second electrode E2 on the side surface of the first separation part 11a. The material of the second electrode E2 is usually a metal or alloy, and the metal or alloy has good climbing performance. In other embodiments, the side surface shape of the first separation part 11a can also be adjusted.

For example, the organic material includes a resin, but is not limited thereto. For example, the organic material includes one of acrylic or polyethylene terephthalate, polyimide, polyamide, polycarbonate, epoxy resin, and the like, or a combination thereof.

The display substrate provided by some embodiments of the present disclosure can effectively realize simultaneous etching of the first separation structure and the second separation structure, and has good process compatibility.

In the display substrate provided by some embodiments of the present disclosure, the first separation structure and the second separation structure can be formed by etching after the backplane process is fully completed, and there is no risk such as the presence of adhesive-coating halos.

For example, in the embodiments of the present disclosure, components located in the same layer may be formed from the same film layer by the same patterning process. In the embodiments of the present disclosure, the patterning or patterning process may only include a photolithography process, or include a photolithography process and an etching step, or may include printing, inkjet and other processes for forming a predetermined pattern. The photolithography process refers to a process including film formation, exposure, development, etc., and using a photoresist, a mask plate, an exposure machine, etc. to form a pattern. A corresponding patterning process can be selected according to the structure formed in the embodiments of the present disclosure.

For example, in the embodiments of the present disclosure, the thickness of a component refers to the dimension of the component in a direction perpendicular to the base substrate.

For example, in the embodiments of the present disclosure, the base substrate BS, the buffer layer BF, the insulating layer GI1, the insulating layer GI2, the insulating layer ILD, the planarization layer PLN, and the spacer PS are all made of insulating materials. For example, the material of the base substrate BS includes polyimide, but is not limited thereto. For example, the materials of the buffer layer BF, the insulating layer GI1, the insulating layer GI2, and the insulating layer ILD include inorganic insulating materials. For example, the materials of the planarization layer PLN, the pixel-defining pattern PDL, and the spacer PS include organic insulating materials. For example, the inorganic insulating material includes at least one of silicon oxide, silicon nitride, and silicon oxynitride. For example, the organic insulating material includes one of acrylic, polyethylene terephthalate, polyimide, polyamide, polycarbonate, epoxy resin, and the like, or a combination thereof.

For example, the insulating layer GI1 may also be called a gate insulating layer, the insulating layer GI2 may also be called a gate insulating layer, and the insulating layer ILD may also be called an interlayer insulating layer.

In the drawings of the present disclosure, if (a) is illustrated on the left part of the figure and (b) is illustrated on the right part of the figure, then (a) means that it is located in the display region and (b) means that it is located in the frame region.

Embodiments of the present disclosure further provide a display device, including a display substrate described in any one of the above.

FIG. 28 is a schematic diagram of a display device provided by an embodiment of the present disclosure. As illustrated in FIG. 28, the display device 500 includes a display substrate 100. The display substrate 100 is a display substrate described in any one of the above. The display substrate mentioned in the embodiments of the present disclosure may also be referred to as a display panel. For example, the display substrate may be a flexible display substrate, but is not limited thereto.

On the one hand, for the display substrate (display panel), a separation structure is provided between adjacent sub-pixels and at least one sub-functional layer (for example, a charge generation layer) in the light-emitting functional layer is disconnected at the position where the separation structure is located, thus avoiding crosstalk between adjacent sub-pixels caused by sub-functional layers (for example, charge generation layers) with high conductivity. As such, the display device including the display substrate can also avoid crosstalk between adjacent sub-pixels, thus having a high product yield and high display quality.

On the other hand, because a tandem structure can be used for the display substrate, pixel density is increased. Therefore, the display device including the display substrate has the advantages of a long lifespan, low power consumption, high brightness, high resolution and the like.

For example, the display device can be an organic light-emitting diode display device or the like, and can also be any product or component with a display function such as a TV, a digital camera, a mobile phone, a watch, a tablet, a laptop, a navigator, etc., including the display device. Embodiments of the present disclosure include but are not limited to thereto.

What have been described above are only specific implementations of the present disclosure, but the protection scope of the present disclosure is not limited thereto. All the changes or substitutions easily conceivable for any skilled who is familiar with the present technical field should be covered by the protection scope of the present disclosure. Therefore, the protection scope of the present disclosure should be based on the protection scope of the claims.

1. A display substrate, comprising:
a base substrate, comprising a hole region, a display region, and a frame region located between the hole region and the display region;
a plurality of sub-pixels located in the display region, wherein the sub-pixel comprises a light-emitting element, the light-emitting element has a light-emitting region, the light-emitting element comprises a first electrode, a light-emitting functional layer, and a second electrode, the second electrode is located on a side of the light-emitting functional layer facing away from the base substrate, the first electrode is located on a side of the light-emitting functional layer close to the base substrate, and the light-emitting functional layer comprises a plurality of sub-functional layers;
a first separation structure located in the display region and comprising a first separation part and a second separation part which are stacked, wherein the first separation part is located on a side of the second separation part close to the base substrate; and
a second separation structure located in the frame region and comprising a third separation part and a fourth separation part which are stacked, wherein the third separation part is located on a side of the fourth separation part close to the base substrate,
wherein the second separation part has a first protruding part, the first protruding part protrudes relative to the first separation part, and at least one sub-functional layer of the light-emitting functional layer is disconnected at the first protruding part,
the fourth separation part has a second protruding part, the second protruding part protrudes relative to the third separation part, and at least one sub-functional layer of the light-emitting functional layer is disconnected at the second protruding part,
the first separation structure surrounds the light-emitting region, and
the second separation structure is ring-shaped so as to surround the hole region.

2. (canceled)

3. (canceled)

4. The display substrate according to claim 1, wherein the first separation structure has a gap, the first electrode has a main body part and a connecting part, an orthographic projection of the main body part on the base substrate overlaps an orthographic projection of the light-emitting region on the base substrate, and the connecting part is located at the gap.

5. The display substrate according to claim 1, further comprising an encapsulation layer, wherein the encapsulation layer comprises a first encapsulation layer, a second encapsulation layer, and a third encapsulation layer, the first encapsulation layer, the second encapsulation layer, and the third encapsulation layer are arranged in sequence, the first encapsulation layer is closer to the base substrate than the third encapsulation layer, the first encapsulation layer and the third encapsulation layer have a stacked contact portion, a plurality of second separation structures are provided, an orthographic projection of one of the plurality of second separation structures on the base substrate overlaps an orthographic projection of the second encapsulation layer on the base substrate, and an orthographic projection of another one of the plurality of second separation structures on the base substrate overlaps an orthographic projection of the stacked contact portion on the base substrate.

6. The display substrate according to claim 1, further comprising a barrier dam, wherein the barrier dam is located in the frame region, and the second separation structure comprises a plurality of second separation structures located on both sides of the barrier dam.

7. The display substrate according to claim 1, wherein a thickness of the second separation part is greater than a thickness of the first separation part.

8. The display substrate according to claim 1, wherein a ratio of a thickness of the first separation part to a thickness of the second separation part is greater than or equal to 0.25 and less than or equal to 1.

9. The display substrate according to claim 1, wherein a dimension of the first separation part in a direction perpendicular to the base substrate is smaller than a dimension of the third separation part in a direction perpendicular to the base substrate.

10. The display substrate according to claim 1, wherein the second separation part and the fourth separation part are located in the same layer, wherein the first separation structure and the second separation structure have the same layer structure.

11. (canceled)

12. The display substrate according to claim 1, wherein a count of film layers included in the first separation part is less than or equal to a count of film layers included in the third separation part.

13. The display substrate according to claim 1, wherein a material of the first separation structure comprises a conductive material, and a material of the second separation structure comprises a conductive material.

14. The display substrate according to claim 13, wherein the conductive material comprises a metal and a conductive metal oxide, wherein the second separation part and the fourth separation part are located in the same layer, and the third separation part comprises a portion located in the same layer as the first separation part.

15. (canceled)

16. (canceled)

17. The display substrate according to claim 1, wherein materials of the first separation part and the second separation part are different, materials of the third separation part and the fourth separation part are different, the materials of the first separation part and the third separation part are the same, and the materials of the second separation part and the fourth separation part are the same.

18. The display substrate according to claim 1, wherein materials of the first separation part and the third separation part comprise organic materials, and materials of the second separation part and the fourth separation part comprise inorganic insulating materials.

19. The display substrate according to claim 1, wherein materials of the first separation part and the third separation part comprise organic insulating materials, and materials of the second separation part and the fourth separation part comprise conductive materials.

20. The display substrate according to claim 1, wherein a material of the first separation part comprises an organic insulating material, a material of the second separation part comprises an organic insulating material, and a material of the third separation part comprises an inorganic insulating material, and a material of the fourth separation part comprises a conductive material.

21. (canceled)

22. The display substrate according to claim 20, wherein the second separation structure comprises two sub-separation structures, and second protruding parts of the two sub-separation structures are oppositely arranged.

23. The display substrate according to claim 20, wherein a plurality of second separation structures are provided, the second separation structure further comprises a fifth separation part, a material of the fifth separation part comprises a conductive material, fifth separation parts of the plurality of second separation structures are of an integral structure, and a plurality of fourth separation parts are sequentially arranged around the hole region.

24. The display substrate according to claim 1, further comprising a conductive structure, wherein an orthographic projection of the conductive structure on the base substrate overlaps an orthographic projection of the first separation structure on the base substrate.

25. (canceled)

26. (canceled)

27. The display substrate according to claim 1, wherein the separation structure comprises at least one separation sub-structure, and an orthographic projection of the at least one separation sub-structure on the base substrate at least surrounds one half of an orthographic projection of the light-emitting region on the base substrate.

28. A display device, comprising the display substrate claim 1.
